(19) United States
(12) Patent Application Publication
(10) Pub. No.: US 2025/0008755 A1
(43) Pub. Date: Jan. 2, 2025

(54) PEROVSKITE PHOTOVOLTAIC DEVICES AND METHODS OF MANUFACTURING THEREOF

(71) Applicant: The Research Foundation for The State University of New York, Binghamton, NY (US)

(72) Inventor: Tara Dhakal, Vestal, NY (US)

(21) Appl. No.: 18/744,356

(22) Filed: Jun. 14, 2024

Related U.S. Application Data
(60) Provisional application No. 63/511,502, filed on Jun. 30, 2023.

(51) Int. Cl. H10K 30/86; H10K 30/50; H10K 30/85; H10K 30/88; H10K 71/13; H10K 71/60; H10K 85/10; H10K 85/20; H10K 85/50

(52) U.S. Cl. CPC H10K 30/86; H10K 30/50; H10K 30/85; H10K 30/88; H10K 71/135; H10K 71/60; H10K 85/141; H10K 85/215; H10K 85/50

(57) ABSTRACT

A photoexcitable structure, comprising a lithiated nickel oxide (0.1-10% lithium) hole transport layer; a perovskite layer adjacent to the hole transport layer, configured, upon illumination, to generate photoexcited electrons and holes; an electron transport layer, and a buffer layer between the perovskite and ETL, configured to accept electrons from the buffer layer. The buffer layer is formed by atomic layer deposition, with a plurality of atomic layers of at least one resistive oxide having an aggregate thickness of less than 30 nm, configured to impede hole transfer from the perovskite to the electron transport layer, and impede ion migration and water diffusion. Beneath the HTL is a conductive layer or substrate. Above the ETL is an electrode. The entire structure is encapsulated. An alternate embodiment provides a buffer layer over the ETL.

### CROSS REFERENCE TO RELATED APPLICATIONS

The present application is a non-provisional of, and claims benefit of priority under 35 U.S.C. § 119 (e) from, U.S. Provisional Application No. 63/511,502, filed Jun. 30, 2023, the entirety of which is expressly incorporated herein by reference.

### STATEMENT OF GOVERNMENT SUPPORT

This invention was made with government support under grant number ECCS 17511946, awarded by the National Science Foundation. The government has certain rights in the invention.

### FIELD OF THE INVENTION

The present invention relates to perovskite photovoltaic materials.

### BACKGROUND OF THE INVENTION

To mitigate/fight climate change, fossil fuel free energy technology is needed. Because of the vast amount of sunlight, solar cells can provide all the power needed worldwide currently and in the future. Perovskites are easy to manufacture both in rigid as well as flexible substrates with very low cost compared to most dominant silicon solar cell. The perovskite solar cells are efficient and can be the future low cost solar cell technology if their stability is improved over the known solar cell designs.

Perovskite solar cells based on organometal halide light absorbers have been considered a promising photovoltaic technology due to their superb power conversion efficiency (PCE) along with very low material costs.

In less than a decade the power conversion efficiency (PCE) of perovskite solar cells has jumped from a mere 3.8% to close to its theoretical limit. Perovskite has wide array of attractive features such as high carrier mobility, intense broadband absorption, long diffusion length, band-gap tunability with mixed halogens for use in tandem solar cells and low-cost and simple solution based fabrication technique {1}-{4}.

Even though mesoscopic TiO₂ have achieved the highest performance level thus far, there is a growing interest in an inverted (p-i-n) planar device architecture. One of the main reasons is due to its relatively simple fabrication process without much loss {5}, {6}. The basic p-i-n architecture has an intrinsic absorber sandwiched between hole transport layer (“HTL”) and electron transport layer (“ETL”) or electron blocking layer (“EBL”) and hole blocking layer (“HBL”). A common ETL replacement for TiO₂ in p-i-n architecture is the fullerene derivative, [6,6] phenyl-C61-butyric acid methyl ester (“PCBM”), which are better electron conductors and thus exhibit reduced hysteresis. They also make excellent hydrophobic capping on perovskites to protect from moisture ingress {7}, {8}.

A wide range of both organic and inorganic HTLs have been studied. One of the most important property of HTL, that is desired when working in inverted architecture, is that it must have wide bandgap, which serves a two-fold purpose. First, wider band gap allows more light to go through HTL into the perovskite. Secondly, with wider band gap it will work efficiently to block electrons from going towards the front transparent electrode (e.g., indium-tin-oxide, “ITO”). Inorganic materials are of particular interest due to their high chemical stability that does not affect both ITO underneath and the chemical process that goes on top of it {9}.

Nickel oxide (NiO) is one of the most widely studied materials for HTL. It forms a cubic structure with a wide band gap of ˜3.4 eV and a high work function of ˜5.3 eV {10}, {11}. Intrinsically NiO is a p-type semiconductor with very low conductivity. NiO is stoichiometrically formed with Ni²⁺ oxidation state, but with some oxygen vacancy replaced with Ni³⁺ gives it an enhanced p-type conductivity. Thus, depending on the fabrication process, the stoichiometry changes and thus the conductivity. A deeper work function with a Fermi level around the midgap enhances the Vₒᵥ, but its intrinsic low conductivity results in high series resistance, which in turn affects the current density (J_{sc}) and fill factor (FF).

Doping the NiOₓ is the best way to improve the conductivity and minimize losses. P-type doping of NiO_{X} can be achieved by a mono-valent atom Lithium (Li) and it has been demonstrated effectively on NiO_{X} using several techniques such as spin coating {12}, spray pyrolysis {9}, {13}, Pulsed Laser Deposition (“PLD”) {14}, sputtering {15} {16}, etc. It has also been shown that the doping tolerance of NiO_{X} with Li is very high. Up to 25% alloying with Li does not change the crystalline structure of NiO_{X} {17}. The conductivity is shown to improve strongly up to 15% addition of Li {18}.

It has been shown that the Li⁺ ion migration has a specific impact on perovskite solar cell (“PSC”) operation through hysteresis. www.energy.gov/cere/solar/perovskite-solar-cells; en.wikipedia.org/wiki/Perovskite_solar_cell. It is a discrepancy of J-V curves when scanned in the forward and reverse directions and is one of the major obstacles hindering the commercialization of PSCs. The most well-received explanation for hysteresis is due to ion migration and accumulation at the two charge-extraction interfaces that modulate the built-in electric field in PSCs {8}, {19}. It has been shown that the excess charge from Li intercalation is localized on a Pb cation which results in reduction of Pb to Pb⁺ {20}. Due to low activation barrier and diffusion coefficient, ions such as I-, methyl ammonium (CH₃NH₃⁺, MA⁺⁾ {21} tend to migrate easily in perovskite. Although it has applications in switchable photovoltaics (“PV”) {22} and non-volatile memory {23}, ionic movement has adverse effects on the stability of traditional photovoltaic solar cell (“PVSCs”) because the migrating ions can react with metal electrodes.

The degradation in a PVSC usually comes from the absorber's intrinsic instability, exposure to elevated temperature, ultraviolet (“UV”) exposure, and exposure to oxygen and moisture present in ambient atmosphere. Different aspects of the PVSC device have been explored to improve the stability of the device. Because the hybrid (organic-inorganic) absorber consists of a hygroscopic ammonium cation, the perovskite is highly sensitive to the moisture and usually decomposes to PbI₂. Stability can be widely improved by utilizing an inorganic electron transport layer (“ETL”) and a hole transport layer (“HTL”), thus sandwiching the moisture-sensitive perovskite material within them.

Several thin film oxide semiconductors such as TiO₂ and Al₂O₃ have been shown to work as an excellent barrier layer for moisture ingress into the device. It is a simple understanding that the thicker the barrier layer the better the encapsulation. These oxides are very resistive, and thus using a thicker layer as a part of the charge extraction layer is prohibitive. However, a properly placed very thin layer can improve the device stability significantly.

Atomic layer deposition (ALD) is a powerful tool in depositing pinhole-free conformal thin-films with excellent reproducibility and accurate and simple control of thickness and material properties over a large area at low temperatures, making it a highly desirable tool to fabricate components of highly efficient, stable, and scalable PSCs. Park, Helen Hejin. “Inorganic materials by atomic layer deposition for perovskite solar cells.” Nanomaterials 11, no. 1 (2021): 88.

PSCs have challenges relating to long-term stability of the working devices from both external and internal factors. Device deterioration from internal factors include ion migration from the perovskite layer and from dopants of hole transport layers diffusing out into the perovskite, whereas external factors include deterioration from exposure to light, elevated temperatures, and air (moisture and oxygen). Atomic layer deposition (ALD) is a powerful tool for growing reproducible conformal pinhole-free high-quality thin-films of inorganic materials. ALD has the advantage of precise fine control of the film thickness and materials properties, such as stoichiometry, morphology, and doping. ALD is a low-vacuum and low-temperature deposition technique, which allows excellent conformal and uniform coating of 3D structures and precise control of film thickness due to its self-limiting chemisorption of precursors during the ALD cycle.

Deposition condition restrictions arise in the case of utilizing ALD to deposit layers on top of the perovskite layer due to the perovskite and/or organic HTL's susceptibility to thermal energy, moisture, and exposure to certain ALD precursors (including H₂O) and low vacuum levels for extended periods of time.

The steps involved in a single ALD cycle process involves a metal precursor pulse exposed to the substrate, followed by a purging step with a carrier gas, followed by the co-reactant pulse exposed to the substrate, followed by another purging step with a carrier gas. The ALD cycle is repeated until the desired thickness is achieved. Deionized water has shown to be the least damaging to the perovskite active layer, among the various co-reactants for the oxygen precursor (H₂O, ozone, and O₂ plasma). A study showed that ALD Al₂O₃ by trimethylaluminum (TMA) and ozone resulted in a complete loss of the MAPbI₃₋ₓClₓ phase, and bleached the perovskite layer, while another study showed that O₂ plasma processes resulted in partial degradation of MAPbI₃ to PbI₂ even at a very low deposition temperature of 30° C. Each pulse step (the metal precursor and the co-reactant) influences the perovskite active layer in somewhat contradicting ways. While a study reported to not observe any degradation of the perovskite after exposure of repeated pulses of TMA and H₂O at 80° C., several studies reported the loss of nitrogen, implying etching of MA⁺ from the perovskite active layer. A study found that TMA partial pressures of 0.1 Torr can etch MAPbI₃ at 75° C., and observed continual mass loss of perovskite at high TMA exposures of 3 Torr at 25° C., suggesting that variations in ALD process parameters result in very different perovskite surfaces, which may explain the discrepancies in literature. For ALD SnO₂ growth by TDMASn and H₂O, a study reported unaltered perovskite surface composition and bulk crystallinity after a >11 Torr exposure of TDMASn at 120° C. However, another study observed removal of FA⁺ from the perovskite surface and formation of PbI₂ after exposure to 60 cycles of TDMASn and H₂O. In addition, these results indicated that the TDMASn has a stronger effect on the perovskite degradation compared to H₂O. Based on these previous results, the general consensus appears to be that deposition temperatures below 100° C. and H₂O co-reactants are preferred in avoiding etching of the perovskite surface and bulk degradation.

Although directly on top of the perovskite absorber layer, passivation layers only require 1 nm or less, so the duration of the absorber material to be exposed to elevated temperatures, ALD precursors, and low vacuum level is rather short (within 10 min). However, as charge transport layers normally require larger thicknesses around 40 nm, this especially becomes an issue if the thick CTL is directly on top of the perovskite absorber. Thus, there are approaches where the perovskite absorber is protected with various other layers to avoid direct exposure of the perovskite surface to the ALD processing conditions. To avoid direct exposure of ALD precursors to the perovskite active layer, an organic ETL, such as C₆₀ or [6.6]-phenyl C₆₁ butyric acid methyl ester (PCBM), or organic HTL, such as PTAA, are typically used as an interfacial layer to protect the perovskite from surface etching and/or bulk degradation. Based on XRD analysis, approximately 50 nm of PTAA was sufficient enough to protect the underlying perovskite active layer from ALD processing damage, whereas direct CuOₓ deposition on top of the bare perovskite surface resulted in bulk degradation.

With ALD aluminum-doped zinc oxide (AZO) in between PCBM/BCP and the top electrode, the degradation of the perovskite absorber from external water and evaporation of methylammonium (MA) was retarded at elevated temperatures of 85° C. The high conductivity of AZO also enabled efficient charge extraction from [6,6]-phenyl C₆₁ butyric acid methyl ester (PCBM) transferred to the top silver (Ag) electrode. ALD AZO was deposited from trimethylaluminum (TMA), diethylzinc (DEZ), and H₂O as the aluminum, zinc, and oxygen precursors, respectively.

A very thin layer (<1 nm) directly on top of the perovskite absorber, known as the passivation or barrier layer, has been shown to be very effective in not only improving the solar cell device performance, through improvement in open-circuit voltage and fill factor, but also in improving the device stability. Lu, Z.; Wang, S.; Liu, H.; Feng, F.; Li, W. Improved Efficiency of Perovskite Solar Cells by the Interfacial Modification of the Active Layer. Nanomaterials 2019, 9, 204.

Such improvement in operational stability can be explained via providing a barrier between the perovskite and charge transport layer, or surface passivation of the perovskite layer. While similar surface passivation concepts have been demonstrated by forming a two-dimensional perovskite on top of the three-dimensional perovskite layer by solution processing, some common barrier layers have also been investigated by ALD resulting in improved device stability to moisture and light. Several groups have demonstrated barrier layers by ALD using aluminum oxide (Al₂O₃) and zirconium oxide (ZrO₂).

Inserting an ultra-thin (<1 nm) Al₂O₃ passivation layer in between the perovskite absorber and spiro-OMeTAD in the conventional n-i-p structured PSC, resulted in improved device performance through enhanced V_{OC} and fill factor. Koushik, D.; Verhees, W.J.H.; Kuang, Y.; Veenstra, S.; Zhang, D.; Verheijen, M.A.; Creatore, M.: Schropp, R.E.I. High-efficiency humidity-stable planar perovskite solar cells based on atomic layer architecture. Energy Environ. Sci. 2017, 10, 91-100. The Al₂O₃ passivation layer not only improved the PCE of the PSC, but also resulted in reduced hysteresis and stabilized the device against high humidity. Based on X-ray diffraction (XRD) scans of perovskite films after exposure to humidity, samples without Al₂O₃ resulted in the appearance of a PbI₂ (001) diffraction peak as a result of decomposition of MAPbI₃, whereas samples with Al₂O₃ did not show the appearance of this peak. Photovoltaic performance monitoring after exposure to humid conditions also resulted in more stable PSCs for devices with the Al₂O₃ passivation layer.

Investigation of ZrO₂ passivation also resulted in enhanced PCEs from improved V_{OC} values for p-i-n structured PSCs. MAPbI₃ based PSCs showed an enhancement in V_{OC} by 0.1 eV. while MAPbBr₃ based PSCs showed an enhancement in V_{OC} by 0.5 V with insertion of the ZrO₂ passivation layer at the perovskite/ETL interface. Shelf-stability of devices with and without ZrO₂ also showed substantial improvement in stability.

Passivation or protection can also be performed at the CTL/top metal contact interface. A thin (<2 nm) inorganic wide bandgap material gallium oxide (Ga₂O₃) by ALD was inserted in between the ETL and top metal contact, silver (Ag). Ma, J.; Zheng, M.; Chen, C.; Zhu, Z.; Zheng, X.; Chen, Z.; Guo, Y.; Liu, C.; Yan, Y.; Fang, G. Efficient and Stable Nonfullerene-Graded Heterojunction Inverted Perovskite Solar Cells with Inorganic Ga₂O₃ Tunneling Protective Nanolayer. Adv. Funct. Mater. 2018, 28.

Due to Ag and iodine ion diffusion, formation of AgI results in degraded PSC device performance, which is a well-known degradation mechanism. The insertion of Ga₂O₃ results in stabilized devices from preventing formation of AgI. Such a Ga₂O₃ protection layer provides a barrier from the penetration of moisture and hinders the corrosion mechanism from the top Ag electrode, as shown in the normalized performance parameters as a function of ambient storage time for PSCs without and with the Ga₂O₃ protection layer. Furthermore, insertion of this protection layer promotes suppressed carrier recombination, decreased current leakage, and improved interfacial contact.

Recombination layers in tandem applications are required to be conductive with high infrared transparency to electrically and optically integrate to top and bottom solar cells. Aluminum-doped ZnO (AZO) has been one of the commonly explored recombination materials by ALD to replace the conventional sputtered indium tin oxide (ITO) recombination material. Incorporation of an ALD AZO recombination layer into all-perovskite monolithic tandems has been demonstrated. Recombination layers are critical in monolithic two-terminal tandems in electrically and optically integrating the top and bottom subcells.

It is also critical to develop fabrication processes of the recombination layer that does not damage the bottom subcell, but also make sure the recombination layer is not damaged from the fabrication processes for the top subcell. Previous studies report that a nucleation layer of an ultra-thin polymer, poly(ethylenimine) ethoxylated (PEIE), enables nucleation of a conformal low-conductivity AZO layer by ALD. This method is stated to allow ALD-grown recombination layers which reduce shunting and solvent degradation from solution processing of the layers from the top cell.

Compared to opaque devices with a metal top contact, semitransparent and tandem applications require a semitransparent top contact to replace the opaque metal top contact. The most common transparent electrode technique used is a transparent conducting oxide (TCO), such as ITO and indium zinc oxide (IZO), by sputtering. However, this usually requires a buffer layer in below the sputtered TCO, to protect the underlying organic CTL from sputtering damage during the TCO processing. Commonly used sputter buffer layers in p-i-n structured perovskite top cells in tandem applications are tin oxide (SnO₂) or SnO₂ followed by zinc tin oxide (ZTO) by ALD to further improve the band alignment at the buffer/TCO interface, resulting in stable semitransparent PSC under 1-SUN illumination. Thermally evaporated molybdenum oxide (MoOₓ) has been the standard buffer layer in semitransparent n-i-p PSCs, however, it suffers from poor air stability. ALD copper oxide (CuOₓ) and vanadium oxide (VOₓ) have also been reported as buffer layers in semitransparent PSCs. Growth methods by pulsed-chemical vapor deposition (pulsed-CVD) or atmospheric-pressure chemical vapor deposition (AP-CVD) have been reported for CuOₓ buffer layers in n-i-p structured semitransparent PSCs. CuOₓ films by AP-CVD resulted in high mobilities over 4 cm²/V·s, and semitransparent PSCs with these buffer layers resulted in PCEs over 16%.

Encapsulation is required for most PSCs to protect the layers from external environmental factors, such as oxygen and moisture. Several reports demonstrated successful encapsulation of PSC devices by ALD single materials or nanolaminates of multiple stacks of alternating materials by ALD and/or organic materials. For example, encapsulated semitransparent PSC devices with a bilayer of 50-nm Al₂O₃-coated polyethylene terephthalate (PET) resulted in stable devices based on storage in ambient air for over 45 days.

While ALD has many advantages, such as accurate control of stoichiometry and thickness with excellent reliability, for certain layers, especially thicker layers (over about 15 nm) above the perovskite absorber, extended duration under exposure to elevated temperatures, certain ALD precursors, and low vacuum, can result in detrimental effects on the perovskite and/or organic CTL. Zardetto, V.V.; Ben Williams, B.; Perrotta, A.A.; Di Giacomo, F.; Verheijen, M.M.; Andriessen, R.; Kessels, W.M.M.; Creatore, M. Atomic layer deposition for perovskite solar cells: Research status, opportunities and challenges. Sustain. Energy Fuels 2017, 1, 30-55.

Most ALD processes in PSCs are generally desired to be deposited at low temperatures (<100° C.) if possible to minimize thermally induced stress. In regards to damage due to exposure from ALD precursors, there have been studies showing reduction of stretching and bending modes of N—H with increasing ALD Al₂O₃ cycles, based on in situ infrared spectroscopy, which implies loss of nitrogen from etching of the MA⁺ in the perovskite lattice. Thus, variations from the conventional ALD are required to minimize deposition time and exposure to degradation sources.

Some common examples are pulsed-CVD, AP-CVD, and s-ALD. Pulsed-CVD involves reducing the carrier purging step during the ALD sequence and pulsing the ALD precursors simultaneously, instead of separately, to reduce the deposition time. From such variation to the conventional ALD method, pulsed-CVD growth methods can reduce the overall deposition time by over an order of magnitude. In the case of atmospheric-pressure spatial-ALD methods, vapors of precursors are carried through gas lines to the reactor head and flow out of separate channels. Here, metal precursors and co-reactant channels are separated by inert gas channels, to prevent precursors reacting above the substrate, and the heated moving substrate is cycled below the gas head and channels. Some labs reported the use of s-ALD of NiO and SnO₂ for the HTL and ETL, respectively. A rapid-vapor phase deposition method, or AP-CVD methods have also shown to be successfully incorporated for buffer layers in semitransparent PSC devices.

See: U.S. Pat. Nos. 9,214,574; 9,349,967; 9,570,240; 9,640,767; 9,711,760; 9,768,404; 9,773,991; 9,793,056; 9,799,841; 9,896,462; 9,911,540; 9,972,780; 9,997,661; 10,002,716; 10,005,800; 10,056,555; 10,079,189; 10,090,468; 10,109,795; 10,199,528; 10,214,833; 10,236,401; 10,253,559; 10,283,279; 10,332,689; 10,374,181; 10,388,465; 10,418,186; 10,431,702; 10,457,148; 10,497,882; 10,535,791; 10,544,168; 10,547,011; 10,566,564; 10,587,221; 10,593,881; 10,608,137; 10,622,574; 10,644,179; 10,651,401; 10,700,236; 10,707,425; 10,720,282; 10,734,165; 10,763,437; 10,770,239; 10,784,449; 10,797,250; 10,844,658; 10,879,479; 10,892,416; 10,907,050; 10,907,092; 10,930,442; 10,950,810; 10,964,896; 10,978,650; 10,984,959; 11,043,335; 11,050,034; 11,056,666; 11,063,164; 11,101,079; 11,158,830; 11,171,290; 11,177,078; 11,177,396; 11,205,735; 11,205,757; 11,228,009; 11,276,885; 11,282,973; 11,300,870; 11,306,243; 11,306,245; 11,312,738; 11,317,618; 11,338,319; 11,362,229; 11,387,421; 11,489,081; 114,89,082; 11,524,947; 11,530,303; 11538998; 11,594,382; 11,597,653; 11,621,402; 11,657,983; 11,659,723; 11,659,725; 11,683,944; 20150053259; 20150071319; 20150122314; 20150129034; 20150136232; 20150144196; 20150243444; 20150249170; 20150249172; 20150279573; 20150287852; 20150295194; 20150311364; 20150318477; 20160002392; 20160005986; 20160013434; 20160035496; 20160049585; 20160079552; 20160133672; 20160149145; 20160155974; 20160218307; 20160225999; 20160226011; 20160233439; 20160248028; 20160254472; 20160268528; 20160285021; 20160293858; 20160293872; 20160315277; 20160322167; 20160322172; 20160329159; 20160343965; 20160351841; 20160359119; 20160380204; 20170012404; 20170018369; 20170018371; 20170018372; 20170028731; 20170053746; 20170084399; 20170084841; 20170092866; 20170098514; 20170125172; 20170133163; 20170148579; 20170149004; 20170155358; 20170162809; 20170186559; 20170186893; 20170194103; 20170207033; 20170213651; 20170221639; 20170229250; 20170244057; 20170250030; 20170260218; 20170263385; 20170268128; 20170271622; 20170278643; 20170287649; 20170288159; 20170301479; 20170301480; 20170309407; 20170330693; 20170331069; 20170338045; 20170338430; 20170342316; 20170346031; 20170358398; 20170365418; 20170373250; 20180005762; 20180006241; 20180006254; 20180016456; 20180019358; 20180022865; 20180033983; 20180033984; 20180033985; 20180075977; 20180075978; 20180096796; 20180105543; 20180108491; 20180108492; 20180114648; 20180122584; 20180142148; 20180151813; 20180174762; 20180194786; 20180198068; 20180204709; 20180208611; 20180211792; 20180212148; 20180216249; 20180218845; 20180219166; 20180226202; 20180226203; 20180226594; 20180230023; 20180233296; 20180240606; 20180244893; 20180247769; 20180247770; 20180248142; 20180254421; 20180259990; 20180261394; 20180269004; 20180277309; 20180282861; 20180286998; 20180294106; 20180301286; 20180301646; 20180308642; 20180309062; 20180309077; 20180315939; 20180330889; 20180342630; 20180350527; 20180350528; 20180350529; 20180351123; 20180358571; 20180366277; 20180366539; 20180366657; 20180370811; 20180374651; 20180374655; 20190003074; 20190006537; 20190006540; 20190013155; 20190019628; 20190019843; 20190027317; 20190036047; 20190044080; 20190051464; 20190051830; 20190066931; 20190067497; 20190088417; 20190093010; 20190096590; 20190097144; 20190105812; 20190122828; 20190131926; 20190148574; 20190157581; 20190164699; 20190165192; 20190173025; 20190181290; 20190189944; 20190198259; 20190206630; 20190214581; 20190221371; 20190221374; 20190221690; 20190221691; 20190221692; 20190221742; 20190221748; 20190221764; 20190229285; 20190233953; 20190237267; 20190237598; 20190237672; 20190237693; 20190272960; 20190279825; 20190288207; 20190292375; 20190312155; 20190326065; 20190345176; 20190362905; 20190363202; 20190379000; 20200013558; 20200020820; 20200028005; 20200028022; 20200028081; 20200051753; 20200052227; 20200058819; 20200066998; 20200075265; 20200075812; 20200075862; 20200083393; 20200105481; 20200106019; 20200111981; 20200119206; 20200127204; 20200136073; 20200140439; 20200143995; 20200161060; 20200161483; 20200168822; 20200176196; 20200176618; 20200176622; 20200194686; 20200203614; 20200212243; 20200225367; 20200235316; 20200239499; 20200243770; 20200251654; 20200273629; 20200277313; 20200294727; 20200294728; 20200295209; 20200308149; 20200313093; 20200325032; 20200325391; 20200335285; 20200335330; 20200343053; 20200354630; 20200361955; 20200361968; 20200369824; 20200373091; 20200373498; 20200373502; 20200373507; 20200377532; 20200377533; 20200381183; 20200381573; 20200381642; 20200382055; 20200388442; 20200388769; 20200395494; 20210005397; 20210005832; 20210028381; 20210036249; 20210040598; 20210054288; 20210057169; 20210070770; 20210070776; 20210083132; 20210091323; 20210098201; 20210098202; 20210104366; 20210104686; 20210119127; 20210122773; 20210122877; 20210125790; 20210126147; 20210135026; 20210142955; 20210143351; 20210151701; 20210159356; 20210159419; 20210166885; 20210167308; 20210175450; 20210193396; 20210193929; 20210198120; 20210198188; 20210210685; 20210210689; 20210210707; 20210214609; 20210217968; 20210217974; 20210218081; 20210233717; 20210242418; 20210249196; 20210257167; 20210273127; 20210273185; 20210280730; 20210280791; 20210288277; 20210292344; 20210296618; 20210313120; 20210319957; 20210327654; 20210366662; 20210367159; 20210367175; 20210375556; 20210383977; 20210383978; 20210395279; 20210399246; 20210408413; 20210408414; 20220002618; 20220005965; 20220006020; 20220013303; 20220013740; 20220025195; 20220029044; 20220029098; 20220029117; 20220033342; 20220037597; 20220044878; 20220052262; 20220052303; 20220076897; 20220077411; 20220077412; 20220085226; 20220085749; 20220093345; 20220108847; 20220109077; 20220109402; 20220115547; 20220115602; 20220122782; 20220123222; 20220131078; 20220135442; 20220135851; 20220139636; 20220140166; 20220140177; 20220140269; 20220145017; 20220148818; 20220149301; 20220158104; 20220173365; 20220181580; 20220199332; 20220205106; 20220209039; 20220216439; 20220223352; 20220231233; 20220231242; 20220235076; 20220235238; 20220238807; 20220246362; 20220246865; 20220246872; 20220263025; 20220263042; 20220271235; 20220277902; 20220285639; 20220285640; 20220285642; 20220302401; 20220310929; 20220320445; 20220328764; 20220336764; 20220359128; 20220359824; 20220363812; 20220376194; 20220380893; 20220384727; 20220384751; 20220393053; 20220406958; 20220407009; 20220416099; 20220416107; 20230006141; 20230006148; 20230019802; 20230020962; 20230022255; 20230027415; 20230042945; 20230050182; 20230050702; 20230064765; 20230068976; 20230073741; 20230074348; 20230083628; 20230084039; 20230087893; 20230088816; 20230092935; 20230096010; 20230096595; 20230096903; 20230099136; 20230099482; 20230099923; 20230102880; 20230105166; 20230110770; 20230114517; 20230114948; 20230119125; 20230120127; 20230129635; 20230141956; 20230145517; 20230157158; 20230161057; 20230165129; 20230170156; 20230178307; 20230180490; 20230181096; 20230189540; 20230197353; 20230200096; and 20230200202.

### Incorporation by Reference and Interpretation of Language

Citation or identification of any reference herein, in any section of this application, shall not be construed as an admission that such reference is necessarily available as prior art to the present application. The disclosures of each reference disclosed herein, whether U.S. or foreign patent literature, or non-patent literature, are hereby incorporated by reference in their entirety in this application, and shall be treated as if the entirety thereof forms a part of this application.

All cited or identified references are provided for their disclosure of technologies to enable practice of the present invention, to provide basis for claim language, and to make clear applicant's possession of the invention with respect to the various aggregates, combinations, and subcombinations of the respective disclosures or portions thereof (within a particular reference or across multiple references). The citation of references is intended to be part of the disclosure of the invention, and not merely supplementary background information. The incorporation by reference does not extend to teachings which are inconsistent with the invention as expressly described herein (which may be treated as counter examples), and is evidence of a proper interpretation by persons of ordinary skill in the art of the terms, phrase and concepts discussed herein, without being limiting as the sole interpretation available.

The present specification is not to be interpreted by recourse to lay dictionaries in preference to field-specific dictionaries or usage by persons of ordinary skill in the art. Where a conflict of interpretation exists, the hierarchy of resolution shall be the intrinsic evidence represented by the express specification, references cited in the specification supporting propositions, and incorporated references in general, and then extrinsic evidence represented by the inventors' prior publications relating to the field, academic literature in the field, commercial literature in the field, field-specific dictionaries, lay literature in the field, general purpose dictionaries, and common understanding.

### SUMMARY OF THE INVENTION

Perovskite solar cells (PSCs) are subject to both extrinsic instability due to external stimuli such as heat, oxygen, and moisture, as well as intrinsic instability from halide movement within the perovskite material. However, the halides may be confined to the perovskite layer and their diffusion prevent out of the perovskite to surrounding charge transport layer prevented using 2D perovskites and an ultra-thin layer of atomic layer deposition (ALD) grown buffer layers that mitigate ion migration.

The technology provides perovskite solar cells manufactured with particular buffer layers, encapsulation methods, and scaffolding to improve the stability and durability of the modules while also retaining flexibility and photovoltaic efficiency. These modifications minimize the effects of extrinsic (e.g., moisture, heat) and intrinsic (halide movement within the perovskite layer) factors that drive solar cell degradation.

The typical layer structure of this technology is Substrate/Li—NiOₓ/Perovskite/buffer layer/PCBM/electrode/encapsulant.

The present technology is based on mixed cation halide perovskite [CsFAMA(Pb/Sn)X₃ (X═I, Br, Cl)]. Addressing the shortcomings of previous perovskite-based technologies, the present technology has improved stability by addressing both extrinsic (e.g., moisture, heat) and intrinsic (halide movement within the perovskite material) factors of cell degradation. Halides are confined to the perovskite layer, preventing their diffusion to surrounding charge transport layers. The technology employs 2D perovskites and an ultra-thin layer of atomic layer deposition (ALD) coated buffer layers that greatly mitigate ion-migration. As an added benefit, the buffer layers act as good moisture barriers, enhancing protection against extrinsic degradation factors. The technology addresses instability challenges from the inside-out, leveraging buffer layers and encapsulation methods to provide superior durability.

The PSC according to the present technology preferably has a structure with a substrate, e.g., transparent glass, through which the illumination passes, which is coated with a layer of lithiated nickel oxide as a hole transport layer. The perovskite photovoltaic material is formed as a layer over the lithiated nickel oxide. An electron transport layer, e.g., PCBM is formed over the Perovskite layer. Directly over ETL, a buffer layer, i.e., atomic layer deposition formed layers of metal oxide, are deposited. The buffer layer is sufficiently thin to permit electrical conductivity, and is followed by a conductive electrode layer, such as Al, Ni, Al/Ni, Ag, or Au. The electrode is covered with an encapsulant, such as an Al₂O₃/TiO₂/SiO₂ based encapsulant coating.

The perovskite solar cell technology disclosed here has following features over other perovskites that will provide the disclosed technology market adoption advantages: (1) Anti-solvent-free synthesis allowing easy printing and scalability; (2) Unique design of 3D/2D perovskites and Atomic Layer Deposition (“ALD”) coated buffer layers; and (3) Moisture barriers for the cell using unique set of ALD coated oxides, which also are anti-reflection layers and thus greatly enhance light absorption.

The technology may use a silicon solar cell as a tandem partner. The buffer layers can be used for other solar cell absorbers. The encapsulant layers may be used for other electronic devices as well.

Inkjet printing techniques may be used for certain layers in the fabrication of mid-size PV modules compatible for interlocking at edges. This allows greater control over printing homogeneity, while also enabling modules to be pieced together into larger cells.

The perovskite solar cells may be manufactured using previously published approaches, with the addition of the formation of the new buffer layer at the junction of the perovskite and the ETL. Meng L, You J, Yang Y. Addressing the stability issue of perovskite solar cells for commercial applications. Nature communications 2018; 9 (1): 5265.

### Substrate

The substrate may be, for example, glass, indium-tin-oxide (ITO), polyethylene terephthalate (PET), or polyimide (PI), the later three permitting flexible solar cells. Indeed, flexible glass may be used as well.

Flexible substrates are advantageous to use given that they are light and can processed at low temperatures at a low cost, even when prepared using roll-to-roll manufacturing. They can also be more readily incorporated in many products for indoor or outdoor use.

As an alternative, a PSC may be fabricated on a metal mesh (e.g., silver or nickel), which display exceptional electrical conductivity, mechanical flexibility, and optical transparency. To enhance the bendability of these materials, the metal meshes will be combined with TCO, conducting polymers, or carbon nanomaterials.

### Lower Electrode

A transparent conductive layer, such as indium-tin-oxide (ITO) is formed over the substrate. In general, the electrode should be, in addition to being highly transparent, non-reactive with the adjacent layers and not highly sensitive to any halides that might migrate from the absorber layer.

### Hole Transport Layer

The present technology encompasses the doping of nickel oxide with Li to affect the electrical and optical properties of PSCs. The Li variated NiO_{X} may be used as an HTL to fabricate the PSCs. Li-doping has been identified to improve the quality of perovskite absorber by passivating the grain boundaries.

NiO_{X} has proven to be an excellent candidate as a hole transport layer in perovskite solar cells. A stoichiometric form of NiO_{X} has intrinsically low conductivity. Intrinsic doping with Ni vacancies creates Ni³⁺, which adds to p-type conductivity of the film, but it can further be improved. Doping with lithium has shown to improve the electrical properties of NiO_{X}. Fabricating a NiO_{X} thin film with added lithium concentration up to 10%, annealed at 300° C., does not significantly change the conductivity or change the band gap, however, the Lithium diffuses into the subsequent device layers and results in improved absorber properties and enhanced the solar cell performance. All aspects of the current-voltage characteristics were improved with the addition of lithium, giving a device having a maximum of 19.3% efficiency at 8% lithium concentration in NiO_{X}. While the open circuit voltage improved slightly with Li incorporation, the operating efficiency improved mainly due to the increases in the short circuit current density (J_{sc}) and the fill factor (FF).

Additionally, other hole transport layers used may be PEDOT: PSS, CZTS, CuSCN, Cu₂O, PTAA and Sprio-MeOTAD.

### Perovskite

The present technology provides a stable perovskite solar cell that has a projected lifetime of 30 years or more. The solar cell layer uses mostly inorganic charge transport layers to improve the stability of the device. The perovskite absorber layer uses an ABX₃ type of organic-inorganic hybrid halide perovskite layer mixed with 2D perovskite, such as Phenylethylammonium iodide (PEAI) and pentafluorophenylethylammonium iodide (F5PEAI), which are tuned to specifically block halide diffusion from the 3D perovskite. The synthesis process is preferably anti-solvent free.

The devices encapsulated using robust encapsulation layers to improve the device efficiency.

The perovskite absorber may have a composition of [(Cs,MA,FA) Pb,Sn X3; X=I,Br,Cl] prepared with two-step process. The coating process doesn't require an anti-solvent which is common in most perovskite solar cell fabrication.

An inter-diffusion based deposition, commonly called 2-step process, suppresses the formation of interstitial iodide, leading to low defect densities than can be achieved from wider distribution of deposition conditions, in comparison to single step approach. Stewart R J, Grieco C, Larsen A V, Doucette G S and Asbury J B 2016 Molecular origins of defects in organohalide perovskites and their influence on charge carrier dynamics J. Phys. Chem. C 120 12392-402.

In the two-step process, the synthesis of perovskite is carried out through the inter-diffusion of the second precursor into the first precursor. Organohalide perovskite films deposited using two-step method exhibit improved uniformity and reproducibility because they do not have to deal with high concentrations of iodoplumbates during film formation. Stewart (2016). The inter-diffusion process is also applicable to substrate with rough surface or with texture. If the first step of the fabrication is achieved conformally (e.g. by vapor deposition) on the surface topography, it allows the overall perovskite to form conformally on the surface irrespective of how the second step is performed. This technique has shown excellent results in tandem solar cell where perovskite is deposited over textured silicon bottom cell. Sahli F and Werner J 2018 Fully textured monolithic perovskite/silicon tandem solar cells with 25.2% power conversion efficiency Nat. Mater. 17 820-6.

Printing methods such as slot dye printing and inkjet printing may be used to form the perovskite layer, as an alternate to spin coating. Printing methods can ensure layer uniformity and over large areas and produce defined patterns. In addition, the PSCs may be fabricated into modules, adapted to be interconnected, and the printed layers may facilitate the efficient interconnection of the modules.

### Buffer Layer

The perovskite solar cell stability improvements may be achieved by incorporating ultra-thin metal oxide layers deposited using low-temperature atomic layer deposition (ALD) technology, to reduce iodide migration in the perovskite layers. This buffer layer, which comprises a bilayer of one or more different metal oxides, effectively prevents ion migration from the perovskite layer as well as the egress of perovskite decomposition products, and is formed directly on the perovskite layer. Brinkmann KO, Zhao J, Pourdavoud N, Becker T, Hu T, Olthof S, Meerholz K, Hoffmann L, Gahlmann T, Heiderhoff R, Oszajca MF, Luechinger NA, Rogalla D, Chen Y, Cheng B, Riedl T. Suppressed decomposition of organometal halide perovskites by impermeable electron-extraction layers in inverted solar cells. Nature Communications 2017; 8 (1): 13938. DOI: 10.1038/ncomms13938.

By suppressing perovskite decomposition, the thermal stability of the device is greatly improved. Bi E, Chen H, Xic F, Wu Y, Chen W, Su Y, Islam A, Gratzel M, Yang X, Han L. Diffusion engineering of ions and charge carriers for stable efficient perovskite solar cells. Nature Communications 2017; 8 (1): 15330. DOI: 10.1038/ncomms15330

The metal oxide buffer layer also improves moisture stability and protects the perovskite solar cells from corrosion, which increases the lifespan of the device.

The buffer layer serves as a hole blocking layer, which blocks hole transfer to the ETL and electrode that would otherwise reduce electron collection efficiency. The buffer layers are directly placed on the perovskites, in contrast with prior work. P. P. Rajbhandari and T. P. Dhakal, “Low temperature ALD growth optimization of ZnO, TiO₂, and Al₂O₃ to be used as a buffer layer in perovskite solar cells,” J. Vac. Sci. Technol. A, vol. 38, no. 3, p. 032406, 2020 (Rajbhandari 2020-1). In Rajbhandari 2020-1, the buffer layers were placed after the ETL (e.g., PCBM) layer. Also, the perovskite (CsMAFAPb) mentioned in P. P. Rajbhandari and T. P. Dhakal, “Limit of incorporating cesium cations into formamidinium-methylammonium based mixed halide perovskite solar cells,” Nanotechnology, vol. 31, p. 135406, 2020 (Rajbhandari 2020-2) didn't have any additives and buffer layers directly on them like the ones disclosed herein.

Note that additional buffer layer(s) may be formed over the ETL. Thus, the stack includes both a hole blocking layer and an electron transport layer over the perovskite. In fact, the increase in efficiency as a result of the prevention of electron-hole recombination by the buffer layer(s) more than makes up for the increase in electrical resistance added by the presence of the buffer layer(s).

Exposure of perovskites to moisture during ALD processes is a risk, as standard ALD recipes use water vapor. The present technology also provides a method of supplying oxygen to the ALD process using ozone, rather than the standard water vapor. Water vapor, even in small concentrations has a detrimental effect on the stability of the underlying perovskite, and is therefore avoided, to reduce moisture-induced degradation to further enhance the lifetime and stability of the fabricated perovskite cells.

The one or more ALD coated thin buffer layers, consisting of e.g., Al₂O₃, ZnO, SnO₂, TiO₂ and/or a combination of these are used directly on top of the perovskite absorber. For example, three different atomic layer deposition (ALD) grown oxide layers, Al₂O₃, TiO₂, and ZnO may be used as a buffer layer, that not only improve charge extraction, but also serve as a good encapsulant for the perovskite absorber layer. In addition, these oxides can be a sputter protection layer that is required for semitransparent perovskite solar cells used in tandem cells.

The effectiveness of these oxide layers is primarily assessed using the current-voltage characteristics of the resulting solar cell devices, and the composition, order, and thickness may be assessed empirically.

The conventional approach of incorporating stabilizing additives within solar cell layers is not enough to hinder halide movement at these boundaries. The use of 2D perovskites and an ultra-thin layer of atomic layer deposition (ALD) coated buffer layers that impedes ion migration helps confine halides to the perovskite layer, and prevents their diffusion out of the perovskite to surrounding charge transport layers.

Of the three metal oxides tested-aluminum oxide (Al₂O₃), titanium oxide (TiO₂), and zinc oxide (ZnO), a bilayer of ZnO and Al₂O₃ provided the optimal buffer layer configuration. It was observed that a 1 nm-thick layer of Al₂O₃ improves the fill factor, current collection, and power conversion efficiency of solar cells and protects them from moisture damage. A thicker barrier layer improves encapsulation but increases resistance, which means that the thickness must be fine-tuned to improve device stability.

The buffer layers may also include SiO₂, and/or SnO₂ layers, for example.

### Electron Transport Layer

The electron transport layer is formed over the buffer layer, and may be, for example, PCBM, Fe₂O₃, ZnO, Al—ZnO, Zn—Sn—O, ZnOS or SnO₂. Traditional ETL technologies may be employed.

### Upper Electrode

The electrode layer can be Al, Ni, Al/Ni, Ag, Au, ITO, or other conductors over the ETL (or additional buffer layer).

### Encapsulant

Extrinsic degradation mechanisms are triggered from external stimuli such as moisture and heat. The device is preferably encapsulated with or ethyl vinyl acetate (EVA), a PolyOlefin (POE) encapsulant, e.g., from HB Fuller, Inc., or a thin film plasmonic optical coating from SunDensity to increase stability or efficiency, respectively.

The encapsulant may also comprise a Al₂O₃/TiO₂/SiO₂ based encapsulant coating, which will also be a strong anti-reflection coating layer for the finished perovskite cell in addition to being the robust moisture barriers.

It is an object to provide a perovskite solar cell, comprising a lithium-doped nickel oxide hole transport layer; a perovskite layer configured, on photoexcitation, to generate photoexcited electrons and holes, wherein the holes are selectively transferred to the hole transport layer; a buffer layer, adjacent to the perovskite layer, formed by atomic layer deposition, configured to conduct the photoexcited electrons from the perovskite layer and to reject holes from the perovskite layer, and mitigate ion migration and water diffusion; and an electron transport layer, adjacent to the buffer layer, configured to accept electrons from the buffer layer. The buffer layer is preferably configured to increase a power conversion efficiency and a stability of the perovskite layer with respect to a perovskite solar cell comprising the lithium-doped nickel oxide hole transport layer, the perovskite layer, and the electron transport layer, and lacking the buffer layer.

The lithium-doped nickel oxide hole transport layer may comprise between 0.1 to 10 mol % lithium, and be disposed on an indium tin oxide conductive layer over a glass substrate.

The electron transport layer may comprise phenyl-C61-butyric-acid-methyl-ester (PCBM).

The buffer layer may comprise metal oxide layers of at least one of aluminum oxide (Al₂O₃), zinc oxide (ZnO), tin oxide (SnO), and titanium dioxide (TiO₂), deposited by atomic layer deposition to a buffer layer thickness of less than 30 nm, grown on the perovskite layer at temperatures below 150° C., and preferably below 100° C., wherein the atomic layer deposition is conducted using a non-aqueous oxygen source. The metal oxide layers comprises each of aluminum oxide (Al₂O₃), zinc oxide (ZnO), tin oxide (SnO), and titanium dioxide (TiO₂) buffer layers, each less than 30 nm thick.

The perovskite solar cell may further comprise a substrate having a conductive surface, disposed beneath the lithium-doped nickel oxide hole transport layer, a conductive layer over the electron transport layer, and an encapsulant over the conductive layer. The encapsulant may comprise atomic layer deposition (ALD) coated nanolaminate comprising aluminum oxide (Al₂O₃), silicon oxide (SiO₂) and titanium oxide (TiO₂), wherein the encapsulant is antireflective, with polyolefin or ethyl vinyl acetate lamination over the nanolaminate. The antireflective nature may be achieved by controlling layer thickness between interfaces having a discontinuity, such as an altered refractive index. See:
en.wikipedia.org/wiki/Anti-reflective_coating
Raut, Hemant Kumar, V. Anand Ganesh, A. Sreekumaran Nair, and Seeram Ramakrishna. “Anti-reflective coatings: A critical, in-depth review.” Energy & Environmental Science 4, no. 10 (2011): 3779-3804.
Khan, S. Bashir, Hui Wu, Chunjiao Pan, and Zhengjun Zhang. “A mini review: Antireflective coatings processing techniques, applications and future perspective.” Res. Rev. J. Mater. Sci 5, no. 4 (2017): 1-19.
Shanmugam, Natarajan, Rishi Pugazhendhi, Rajvikram Madurai Elavarasan, Pitchandi Kasiviswanathan, and Narottam Das. “Anti-reflective coating materials: A holistic review from PV perspective.” Energies 13, no. 10 (2020): 2631.
Moayedfar, Majid, and Morteza Khalaji Assadi. “Various types of anti-reflective coatings (ARCS) based on the layer composition and surface topography: a review.” Reviews on Advanced Materials Science 53, no. 2 (2018): 187-205.
Keshavarz Hedayati, Mehdi, and Mady Elbahri. “Antireflective coatings: Conventional stacking layers and ultrathin plasmonic metasurfaces, a mini-review.” Materials 9, no. 6 (2016): 497.
Law, Adam M., Luke O. Jones, and John M. Walls. “The performance and durability of Anti-reflection coatings for solar module cover glass-a review.” Solar Energy 261 (2023): 85-95.
Ji, Chunxue, Wen Liu, Yidi Bao, Xiaoling Chen, Guiqiang Yang, Bo Wei, Fuhua Yang, and Xiaodong Wang. “Recent applications of antireflection coatings in solar cells.” In Photonics, vol. 9, no. 12, p. 906. MDPI, 2022.

The hole transport layer may be formed on an indium tin oxide (ITO) layer supported by a glass substrate.
Bush, Kevin A., Colin D. Bailie, Ye Chen, Andrea R. Bowring, Wei Wang, Wen Ma, Tomas Leijtens, Farhad Moghadam, and Michael D. McGehee. “Thermal and environmental stability of semi-transparent perovskite solar cells for tandems enabled by a solution-processed nanoparticle buffer layer and sputtered ITO electrode.” Advanced Materials 28, no. 20 (2016): 3937-3943.
Bi, Sheng, Qikun Li, Ying Yan, Kyeiwaa Asare-Yeboah, Tianbao Ma, Chaolong Tang, Zhongliang Ouyang, Zhengran He, Yun Liu, and Chengming Jiang. “Layer-dependent anisotropic frictional behavior in two-dimensional monolayer hybrid perovskite/ITO layered heterojunctions.” Physical Chemistry Chemical Physics 21, no. 5 (2019): 2540-2546.
Chen, Yangxi, Chaoling Du, Lu Sun, Tianyi Fu, Ruxin Zhang, Wangxu Rong, Shuiyan Cao, Xiang Li, Honglie Shen, and Daning Shi. “Improved optical properties of perovskite solar cells by introducing Ag nanopartices and ITO AR layers.” Scientific reports 11, no. 1 (2021): 14550.
Ou, Xia-Li, Ming Xu, Jing Feng, and Hong-Bo Sun. “Flexible and efficient ITO-free semitransparent perovskite solar cells.” Solar energy materials and solar cells 157 (2016): 660-665.
Pandey, Manish, Zhen Wang, Gaurav Kapil, Ajay K. Baranwal, Daisuke Hirotani, Kengo Hamada, and Shuzi Hayase. “Dependence of ITO-Coated Flexible Substrates in the Performance and Bending Durability of Perovskite Solar Cells.” Advanced Engineering Materials 21, no. 8 (2019): 1900288.
Huang, Keqing, Yongyi Peng, Yaxin Gao, Jiao Shi, Hengyue Li, Xindi Mo, Han Huang, Yongli Gao, Liming Ding, and Junliang Yang. “High-performance flexible perovskite solar cells via precise control of electron transport layer.” Advanced Energy Materials 9, no. 44 (2019): 1901419.
Cho, An-Na, and Nam-Gyu Park. “Impact of interfacial layers in perovskite solar cells.” ChemSusChem 10, no. 19 (2017): 3687-3704.

The hole transport layer may be supported by a polyethylene terephthalate (PET) film, e.g., the perovskite solar cell itself is formed as a series of layers on a flexible substrate, advantageously in a roll-to-roll manufacturing process. This permits use of ink jet printing or a mass-transfer printing process to pattern at least one layer.

It is another object to provide a photoexcitable structure, comprising: a perovskite layer adjacent to the hole transport layer, configured to generate photoexcited electrons and holes upon illumination; a lithiated nickel oxide hole transport layer, configured to receive holes from the perovskite layer; an electron transport layer configured to accept photoexcited electrons; and a buffer later comprising a plurality of atomic layers of at least one resistive oxide having a thickness of less than 30 nm, between the perovskite layer and the electron transport layer, configured to impede hole transfer from the perovskite layer to the electron transport layer, and to impede ion and water diffusion.

A substrate having a conductive surface may be provided beneath the lithiated nickel oxide hole transport layer and a conductive layer over the electron transport layer, further comprising an encapsulant over the conductive layer.

The at least one resistive oxide may comprise a metal oxide selected from the group consisting of aluminum oxide, titanium oxide, tin oxide and zinc oxide.

It is a further object to provide a method of forming a perovskite solar cell, comprising: forming a hole transport layer comprising nickel oxide with between 1-10% moles lithium per mole nickel; forming a photoexcitable perovskite layer on the hole transport layer; using atomic layer deposition to deposit layers of an oxide on the perovskite layer; and forming an electron transport layer over the deposited layers of the oxide. The oxygen source for the ALD is preferably non-aqueous, using oxygen and/or ozone as the oxygen source. After an initial water impermeable layer is formed over the perovskite, the process may transition to a water vapor oxygen source, though this then requires evacuation (dehydration) of the deposition chamber before a subsequent deposition process is initiated.

The perovskite layer may comprise at least one halogen, and the layers of the oxide are impermeable to the at least one halogen and water.

The layers of the oxide are preferably more permeable to electrons than to holes, thus inducing a polarity of the cell.

The layers of the oxide may comprise a metal oxide selected from the group consisting of aluminum oxide, titanium oxide, tin oxide, and zinc oxide, deposited using a non-aqueous oxygen source.

The method may further comprise: forming the hole transport layer on a conductive surface supported by a substrate; depositing a conductive layer over the electron transport layer; and forming an encapsulant over the conductive layer, the encapsulant comprising an atomic layer deposition (ALD) coated nanolaminate comprising aluminum oxide (Al₂O₃), silicon oxide (SiO₂) and titanium oxide (TiO₂) configured to be anti-reflective, followed by polyolefin or ethyl vinyl acetate lamination.

At least one layer may be deposited in a pattern by an inkjet process.

The photoexcitable perovskite layer may be formed using a two-step deposition process, comprising: a first step in which a first mixture of lead(II) iodide (PbI₂), lead(II) bromide (PbBr₂), lead(II) chloride (PbCl₂), and cesium iodide (CsI) is prepared in a solvent mixture of dimethyl formamide (DMF) and dimethyl sulfoxide (DMSO) is deposited, dried and heated; and a second step in which a second mixture of formamidinium iodide (FAI) and methylammonium bromide (MABr) are dissolved in anhydrous 2-propanol provided over the dried heated first mixture, and the second mixture is dried and annealed.

The oxide layers may comprise at least one of aluminum oxide (Al₂O₃), zinc oxide (ZnO), tin oxide (SnO), and titanium dioxide (TiO₂) buffer layers each less than 30 nm thick grown at temperatures below 150° C. or preferably below 100° C., formed using trimethyl-aluminum (TMA), dimethyl zinc (DMZ), and titanium tetrachloride (TiCl₄) as metal precursor sources.

It is another object to provide an inverted p-i-n perovskite solar cell, comprising: a lithium-doped nickel oxide hole transport layer; a perovskite layer configured, on photoexcitation, to generate photoexcited electrons and holes, wherein the holes are selectively transferred to the hole transport layer; a buffer layer, adjacent to the perovskite layer, formed by atomic layer deposition, configured to conduct the photoexcited electrons from the perovskite layer and to reject holes from the perovskite layer, and mitigate ion migration and water diffusion; and an electron transport layer, adjacent to the buffer layer, configured to accept electrons from the buffer layer, wherein the buffer layer increases an power conversion efficiency of the perovskite solar cell with respect to a perovskite solar cell lacking the buffer layer.

The inverted p-i-n perovskite solar cell may further comprise a substrate having a conductive surface beneath the lithium-doped nickel oxide hole transport layer.

The inverted p-i-n perovskite solar cell may further comprise a conductive layer over the electron transport layer.

The inverted p-i-n perovskite solar cell further comprising an encapsulant over the conductive layer.

It is a further object to provide a photoexcitable structure, comprising: a lithiated nickel oxide hole transport layer; a perovskite layer adjacent to the hole transport layer, configured, upon illumination, to generate photoexcited electrons and holes; an electron transport layer, adjacent to the buffer layer, configured to accept electrons from the buffer layer; and a plurality of atomic layers of at least one resistive oxide having an aggregate thickness of less than 30 nm, between the perovskite layer and the electron transport layer, configured to impede hole transfer from the perovskite to the electron transport layer, and impede ion and water diffusion.

A substrate having a conductive surface beneath the lithiated nickel oxide hole transport layer may be provided.

A conductive layer may be provided over the electron transport layer.

The photoexcitable structure may further comprise an encapsulant over the conductive layer.

It is another object to provide a method of forming a perovskite solar cell (PSC), comprising: forming a hole transport layer comprising nickel oxide with between 1-10% moles lithium per mole nickel; forming a photoexcitable perovskite layer on the hole transport layer; using atomic layer deposition to deposit layers of an oxide having a non-aqueous oxygen source on the perovskite layer; and forming an electron transport layer over the deposited layers of the oxide.

The layers of the oxide are impermeable to halogen, moisture (water), and may be more permeable to electrons than to holes. The halogen may be fluorine, chlorine, bromine, iodine, and at least in theory, astatine. Typically, the halogen will be one or more of chlorine, bromine, and iodine, and therefore the impermeability of the oxide layers to halogen would be focused on these halogens. To the extent relevant, astatine is a heavy element with a large atomic radius, and would have a lower mobility. If the perovskite includes fluorine, then fluorine mobility in the oxide layers is relevant.

The layers of the oxide comprise one or more of aluminum oxide, titanium oxide, tin oxide, and zinc oxide. The ALD process may use ozone as an oxygen source.

A substrate having a conductive surface may be disposed beneath the hole transport layer.

A conductive layer may be provided over the electron transport layer.

The PSC may further comprise an encapsulant over the conductive layer.

It is a still further object to provide a perovskite solar cell comprising a glass substrate, an indium tin oxide conductive layer, a nickel oxide layer having between 0.1 to 10 mol % lithium electron transport layer, a perovskite layer, a metal oxide layer deposited by atomic layer deposition, a phenyl-C61-butyric-acid-methyl-ester (PCBM) hole transport layer, a silver conductive layer, and an encapsulant, wherein the metal oxide layer is between the perovskite layer and the electron transport layer.

The perovskite layer may be formed using a two-step deposition process, comprising a first step in which a first mixture of lead(II) iodide (PbI₂), lead(II) bromide (PbBr₂), lead(II) chloride (PbCl₂), and cesium iodide (CsI) is prepared in a solvent mixture of dimethyl formamide (DMF) and dimethyl sulfoxide (DMSO) is deposited, dried and heated, and a second step in which a second mixture of formamidinium iodide (FAI) and methylammonium bromide (MABr) are dissolved in anhydrous 2-propanol provided over the dried heated first mixture, and the second mixture is dried and annealed.

The metal oxide layer may comprise one or more of aluminum oxide (Al₂O₃), zinc oxide (ZnO), tin oxide (SnO₂), and titanium dioxide (TiO₂) buffer layers each less than 30 nm thick, grown at temperatures below 150° C., or preferably below 100° C., wherein the atomic layer deposition is conducted using ozone as an oxygen source.

The metal oxide layer may comprise one or more of aluminum oxide (Al₂O₃), zinc oxide (ZnO), tin oxide (SnO), and titanium dioxide (TiO₂) buffer layers each less than 30 nm thick, grown at temperatures below 150° C., or preferably below 100° C., wherein the atomic layer deposition is conducted an oxygen source other than water.

The metal oxide layer may comprise one or more of aluminum oxide (Al₂O₃), zinc oxide (ZnO), tin oxide (SnO₂), and titanium dioxide (TiO₂) buffer layers each less than 30 nm thick, using trimethyl-aluminum (TMA), dimethyl zinc (DMZ), Tetrakis(dimethylamino)Tin (Sn(NME2)₄), and titanium tetrachloride (TiCl₄) as metal precursor sources.

The encapsulant may comprise polyolefin (POE) or ethyl vinyl acetate (EVA).

The encapsulant may comprise ALD coated nanolaminate comprising Al₂O₃, SiO₂ and TiO₂ which is also designed to be an anti-reflection material (antireflection coating) followed by polyolefin or ethyl vinyl acetate lamination.

It is a still further object to provide a perovskite solar cell comprising a flexible polymer substrate, an indium tin oxide conductive layer, a nickel oxide layer having between 0.1 to 10 mol % lithium hole transport layer, a perovskite layer, a metal oxide layer deposited by atomic layer deposition, a phenyl-C₆₁-butyric-acid-methyl-ester (PCBM) electron transport layer, a conductive layer, and an encapsulant, wherein the a metal oxide layer is between the perovskite layer and the electron transport layer.

The flexible polymer substrate may comprise polyethylene terephthalate (PET).

The polyethylene terephthalate (PET) may be flexed around a roll. e.g., manufactured using a roll-to-roll manufacturing process.

At least one layer may be deposited in a pattern by an inkjet process.

### BRIEF DESCRIPTION OF THE DRAWINGS

FIG. 1 shows transmissivity of NiO_{X} film with varying Li concentration from 0-10%.

FIG. 2 shows a Tauc plot of NiO_{X} film with varying Li concentration from 0-10%

FIG. 3 shows photoluminescence spectra of the perovskite absorber over glass and NiO_{X} with Li doping from 0-10%.

FIG. 4 shows XRD of the perovskite absorber grown on NiO_{X} with varying Li concentration from 0-10%.

FIG. 5 shows an SEM cross-section of the PSC with PCBM/ZnO ETL layers.

FIGS. 6A-6D show device performance of PSCs with Li doped NiO_{X} as hole transport layer

FIG. 7 shows IV-characteristics of devices with maximum PCE for each Li concentration.

FIG. 8 shows UPS spectra of NiO_{X} films with varying Li concentration (%) on ITO substrate

FIG. 9 shows energy band of PSCs with varying Li concentration on NiO_{X}.

FIGS. 10A and 10B show the transmission of NiO_{X} spin-coated at 2000 rpm (10A) and 4000 rpm (10B) using 1 M solution and annealed at different temperatures. The thinner NiO_{X} film, spin-coated at 4000 rpm and annealed at 300° C., showed the best transmission than thicker film achieved at 2000 rpm.

FIG. 11 shows XRD of thick NiO_{X} grown with 1M solution spin-coated and annealed at 300° C. and 350° C. showing all three characteristic peaks of cubic NiO_{X} phase.

FIGS. 12A to 12D show Box & Whiskers plots representation of photovoltaic parameters of perovskite solar cell with different molarity of NiO_{X} HTL. The best PCE was achieved using 0.5 M NiO_{X}.

FIGS. 13A to 13D show Box & Whiskers plots representation of photovoltaic parameters of perovskite solar cell with NiO_{X} fabricated using different spin speeds (rpm). It showed that the optimal spin speed for higher PCE is at 5500 rpm, considering its consistently high value.

FIGS. 14A to 14G show XPS comparison of undoped NiO_{X} (left column) and NiO:Li (8%) (right column).

FIG. 15 shows box chart graphics of the resistance of NiO_{X} film with varying amounts of Li doping. It showed a decreasing trend in resistance with Li doping up to 4%. The resistance stayed stable till 8% and then increased at 10% Li.

FIG. 16 shows AFM of NiO_{X} thin film showing a nano-crystalline structure.

FIG. 17 shows an SEM image of NiO_{X} thin film showing a nano-crystalline structure.

FIG. 18 shows the current-voltage (I-V) response of perovskite solar cells with forward and reverse direction scanning.

FIG. 19 a traditional PSC and its sources of instability.

FIG. 20 shows the effect of buffer layers in Perovskites.

FIG. 21 shows details of the structure of the PSC with the buffer layer over the ETL.

FIG. 22 shows the effect of buffer layers in Perovskites.

FIG. 23 shows details of the structure of the PSC with the buffer layer over the perovskite and under the ETL.

### DETAILED DESCRIPTION OF THE PREFERRED EMBODIMENTS

### Example 1

A preferred solar cell is assembled, e.g., with the following layers: glass, indium tin oxide (ITO), lithiated (0.1-10%, preferably 7-8%) nickel oxide (NiOₓ), perovskite, ALD oxides, phenyl-C61-butyric-acid-methyl-ester (PCBM), silver (Ag), and encapsulant.

To fabricate the devices, ITO precoated glass is washed with detergent and sequentially sonicated in acetone and 2-propanol, followed by blow drying with nitrogen. Prior to use, the ITO precoated glass is further exposed to UV-ozone in an oxygen rich atmosphere.

The nickel oxide film is then formed by spin coating the ITO glass substrate with a mixture of nickel nitrate hexahydrate and ethylene diamine in ethylene glycol. If lithium is used, it is doped into the nickel oxide at this stage.

The perovskite layer is formed using a two-step deposition process. In the first step, a mixture of lead(II) iodide (PbI₂), lead(II) bromide (PbBr₂), lead(II) chloride (PbCl₂), and cesium iodide (CsI) is prepared in a solvent mixture of dimethyl formamide (DMF) and dimethyl sulfoxide (DMSO). This mixture is subsequently spin-coated onto the NiOₓ-coated substrate and dried at room temperature or on a hot plate at 50° C. In the second step, a mixture of formamidinium iodide (FAI) and methylammonium bromide (MABr) dissolved in anhydrous 2-propanol is dynamically casted on the substrate, dried at room temperature, and then annealed at 140° C. to produce a 420 nm-thick perovskite film.

The metal oxide buffer layers are grown in an ALD reactor and overlayed on the perovskite layer.

After cooling, PCBM in chlorobenzene is statically spin-coated from a syringe and subsequently annealed at 75° C. to produce a ˜40 nm thick PCBM layer.

An 80 nm thick silver top electrode is deposited in a thermal evaporator using a shadow mask of sizes of 0.09 cm² and 0.04 cm².

To grow aluminum oxide (Al₂O₃), zinc oxide (ZnO), and titanium dioxide (TiO₂) buffer layers, a Sundew Technologies, LLC (Thornton, Colorado, USA) D200 ALD reactor with access to purging gas (nitrogen) may be employed. These layers are grown at low temperatures (i.e., 100° C.), which is within the thermal stability window of most of the perovskite/organic layers. Each metal oxide payer is e.g., less than 30 nm think, and for example, the optimal Al₂O₃ may be 1-3 nm thick, and an Al₂O₃/ZnO bilayer may be 1 nm/3 nm. See, Rajbhandari 2020-1.

Conventional ALD systems use deionized water vapor (Millipore or Milli-Q, maintained at 22° C.) as the oxygen source. However, the moisture sensitivity of perovskites, especially where the buffer layer is deposited directly on the perovskite and not on the ETL formed over the perovskite, presents a challenge to using water in this process. To circumvent this issue, ozone (O₃) is used instead of water vapor as the oxidant. The film growth rate by ozone-based ALD processes is comparable to water-based oxygen processes. Ozone also has the added benefit of reducing the likelihood of hydrogen or hydroxyl contamination in the deposited film as there is no hydrogen in the ozone molecule. The ALD reactor is therefore equipped with an ozone generator. The Al₂O₃ with ozone recipe has demonstrated to be a better dielectric with enhanced breakdown strength compared to water based process. It is also possible to provide both ozone and water together as oxygen sources.

Trimethyl-aluminum (TMA), dimethyl zinc (DMZ), and titanium tetrachloride (TiCl₄), e.g., from STREM Chemicals, may be used as the metal precursors for growing the buffer layer films. All processes are performed under vacuum.

The perovskite-based solar cells are then encapsulated with, for example, polyolefin or ethyl vinyl acetate for environmental protection and mechanical strength or Sundensity's plasmonic optical coating for enhanced device performance by means of down conversion of light photons.

As an alternate process, ITO-coated PET may be fixed to the drum of the roll coater set at 50° C. for the two-step coating process. Nickel oxide (hole-transport layer) is slot-die coated on the substrate. Then, the various additional layers are added.

Inkjet printing processes may also be used for high-throughput and large-scale production of flexible perovskite solar cells. First, a uniform NiOx hole-transport layer (which may be lithium doped) is obtained by printing a nickel(II) acetate dihydrate (NiAc) wet film (with lithium acetate (LiAc) for lithiation) and subsequently annealing at ambient temperatures. Next, a triple cation perovskite layer is printed onto the NiO layer.

The buffer layers are formed by ALD, which requires that the substrate web be placed in a vacuum chamber, with successive cycles of deposition.

A thin layer of PCBM (electron-transport layer) is also be inkjet-printed over the buffer layer as the ETL. Other ETL materials may also be printed on the buffer layer.

The evaporation of the solvent and film crystallization in each printing/coating step can be done though thermal, rapid thermal or flash light annealing.

Moisture Sensitivity. Water droplets will be cast onto the finished perovskite films PSC using a pipette and exposed for 30 seconds. Decomposition of the perovskite films will be determined by checking for discoloration (i.e., yellowing) following water exposure.

Light Stability. The devices will be exposed to continuous light irradiation without an UV-blocking filter. The solar modules will be evaluated using Standard Test Conditions (STCs) using a light irradiance of 1000 W/m² and a solar cell temperature of 25° C., as described in IEC 61215:2016 standard. To achieve the required light irradiance, a two-lamp (halogen and xenon) class AAA WACOM sun simulator with an AM1.5G irradiance spectrum at 1,000 W/m² will be used These tests will also be carried out in ambient air with a relative humidity level of 20-30%. Current density-voltage (J-V) scans will be recorded regularly to monitor electrical parameters during constant illumination.

### Example 2

Process:

ITO coated plain glass substrates are cleaned by sonicating in acetone and isopropyl alcohol followed by UV-ozone treatment for 15 minutes.

Then 0.5 M nickel nitrate hexahydrate and ethylenediamine in ethylene glycol is used to spin coat the NiO_{X}. Doped NiO_{X} was made by adding a controlled percentage of Li nitrate into the 0.5 M solution. Then spin coated film is annealed at 300° C. in air for 1 hr. After annealing, it is taken into the glovebox for further processing.

Perovskite (CsFAMAPb(IBrCl)₃) was fabricated with a 2-step spin coating process. See, P. P. Rajbhandari and T. P. Dhakal, “Limit of incorporating cesium cations into formamidinium-methylammonium based mixed halide perovskite solar cells,” Nanotechnology, vol. 31, p. 135406, 2020. Then it is annealed at 140° C. for 20 minutes.

A buffer layer of ZnO (4 nm)/Al₂O₃ (1 nm) is added using Atomic Layer Deposition (ALD) at 100° C. directly over the perovskite/electron transport layer, using ozone as the oxygen source, and avoiding water. See, P. P. Rajbhandari and T. P. Dhakal, “Low temperature ALD growth optimization of ZnO, TiO₂, and Al₂O₃ to be used as a buffer layer in perovskite solar cells,” J. Vac. Sci. Technol. A, vol. 38, no. 3, p. 032406, 2020. As discussed, the optimal composition, sequence, and thickness of the buffer layer(s) may be determined empirically.

At ambient temperature, 17 mg/ml PCBM in chlorobenzene is spin coated at 2000 rpm for 40 sec and post baked at 70° C. for 2 min.

The PSC is taken to a thermal evaporator outside the glovebox for depositing 100 nm of silver.

Finally, the PSC is encapsulated with a polymer, such as POE or EVA.

Characterization:

The structural characterization of perovskite may be performed with x-ray diffraction (XRD) on a PanAnalytical X′Pert PRO X-ray diffraction system which uses CuKα X-rays and line-focus optics. Carl Zeiss supra 55 VP—high resolution—scanning electron microscope (HR-SEM) may be used to study the morphology of the films. The photoluminescence (PL) may be measured using Horiba's PL measurement system with 532 nm laser and photo multiplier tube (PMT) detector. Transmittance may be measured using the Ångstrom Sun Technologies' TF Probe UV/Vis spectrophotometer. IV characterization may be carried out using Keithley's 4200-SCS semiconductor characterization system along with the solar simulator from Photo Emission Tech. Cells were tested under AM1.5G 100 mW/cm² illumination with the voltage swept in the forward and/or reverse directions with a scan rate of 0.4 V/s. XPS study may be performed using a Surface Science Instruments SSX-100 with operating pressure ˜2×1⁻⁹ Torr. Monochromatic Al Kα x rays (1486.6 eV) with 1 mm diameter beam size may be used. Photoelectrons may be collected at a 55° emission angle. A hemispherical analyzer may determine electron kinetic energy, using a pass energy of 150 V for wide/survey scans, and 50 V for high resolution scans. A flood gun may be used for charge neutralization of non-conductive samples. UPS study may be performed using same tool with He-I as the excitation source.

### Results and Discussion

The optimal thickness of the NiO_{X} film is determined empirically by making devices with varying thicknesses and measuring characteristics. The thickness was controlled using concentration and spin speed during to vary the thickness of the resulting layer in a deposition process.

The optimum and repeatable thickness for NiO_{X} which is obtained at 0.5 Molar concentration of Nickel nitrate hexahydrate and a spin speed of 5500 rpm.

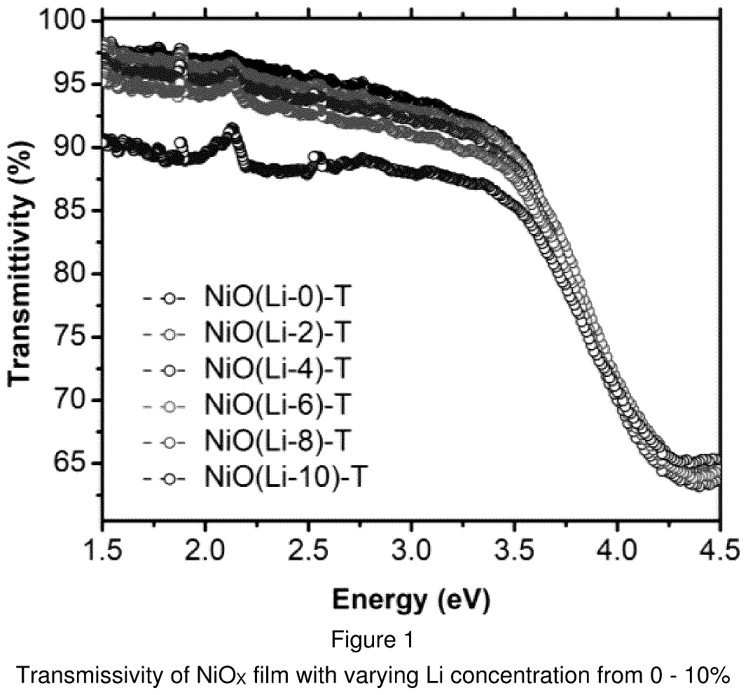

FIG. 1 shows transmissivity of NiO_{X} film with varying Li concentration from 0-10%.

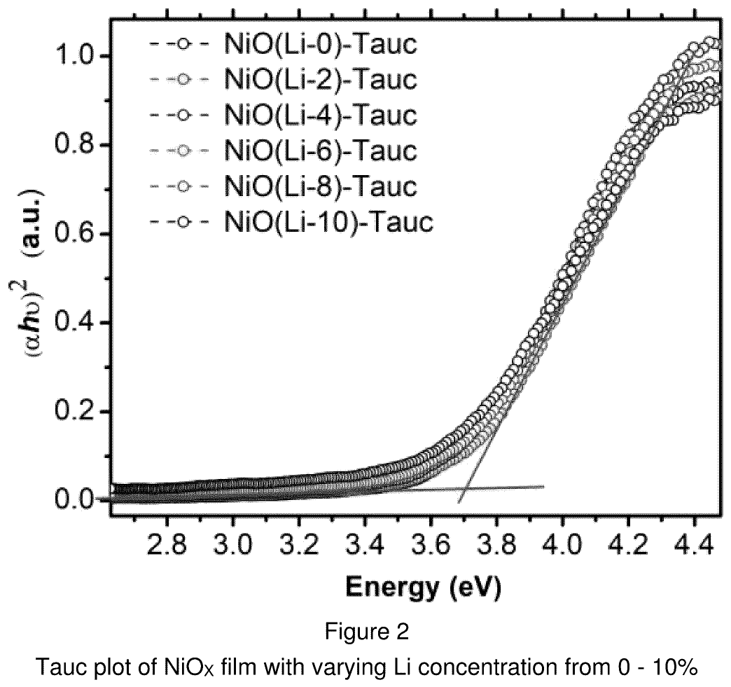

FIG. 2 shows a Tauc plot of NiO_{X} film with varying Li concentration from 0-10%

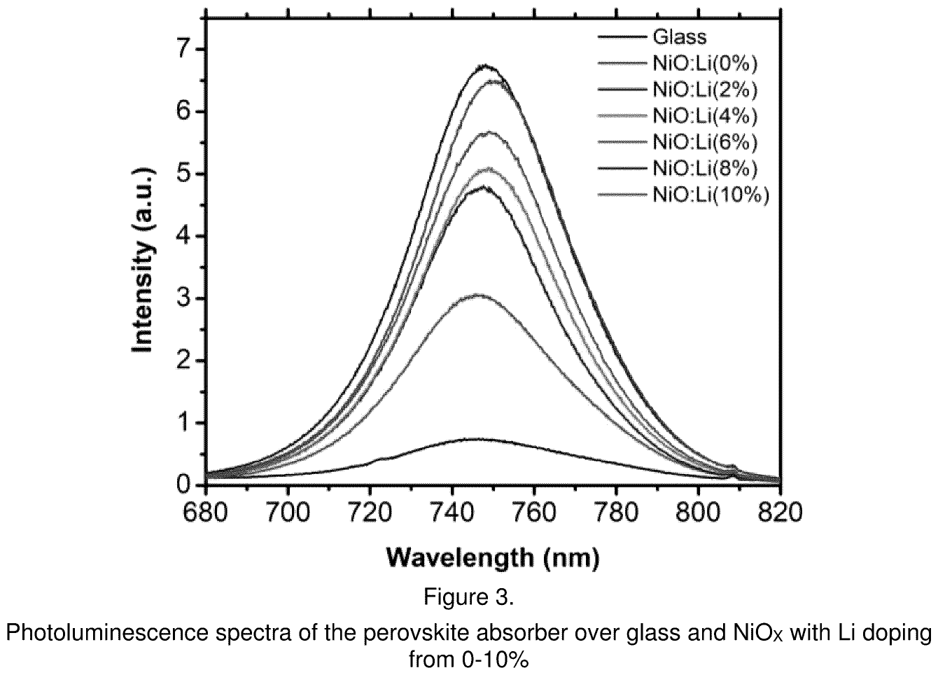

FIG. 3 shows photoluminescence spectra of the perovskite absorber over glass and NiO_{X} with Li doping from 0-10%.

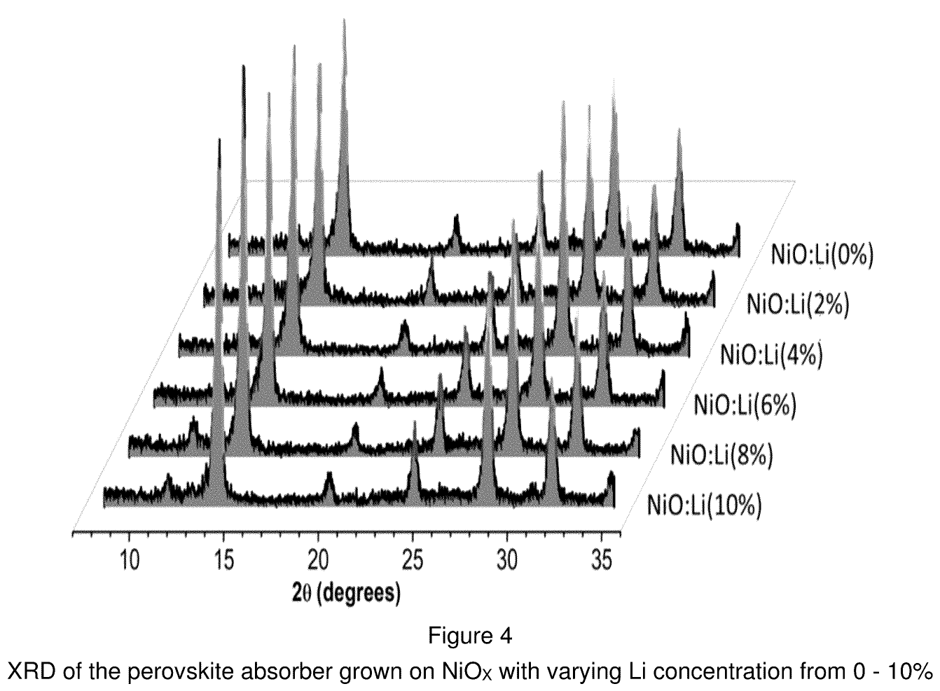

FIG. 4 shows XRD of the perovskite absorber grown on NiO_{X} with varying Li concentration from 0-10%.

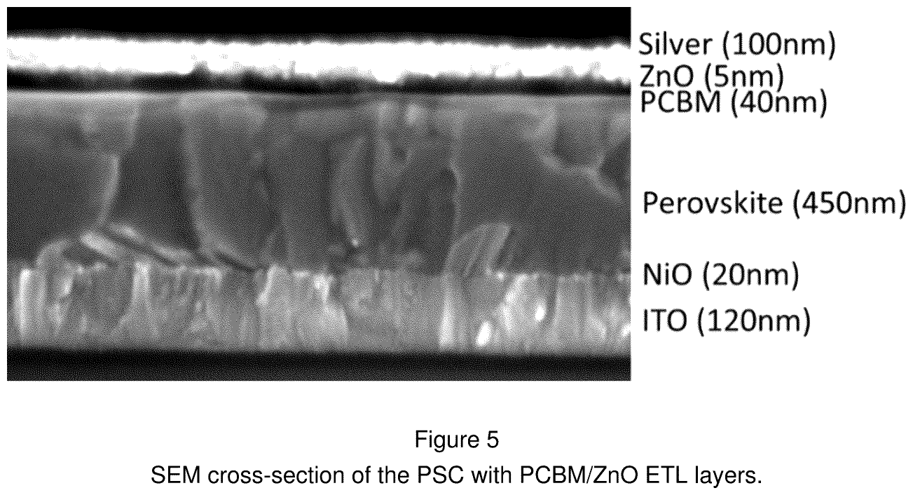

FIG. 5 shows an SEM cross-section of the PSC with PCBM/ZnO ETL layers.

The same recipe was then used to study the influence of Li doping on NiO_{X} and to the overall device. With increase of Li doping up to 8% the transmittance slowly reduced, but at 10% it decreased significantly as seen in FIG. 1.

The tauc plot of the Li variated films did not show significant change in optical bandgap. From 0% Li to 10% Li, the bandgap only shifted from 3.7 eV to 3.67 eV. This is in contrast to a report in the literature which states that with addition of 5% Li, the bandgap is reduced from 3.6 eV to 3.47 eV. W. Chen et al., “Efficient and stable large-area perovskite solar cells with inorganic charge extraction layers.”

The reported results were obtained by annealing at 500° C., whereas in the present study annealing was conducted at 300° C. This could mean that the dopants are not fully activated at low temperature. Sta et. al. also post-annealed the Li doped NiO_{X} up to 600° C. to enhance electrical conductivity. I. Sta, M. Jlassi, M. Hajji, and H. Ezzaouia, “Structural, optical and electrical properties of undoped and Li-doped NiO thin films prepared by sol-gel spin coating method,” Thin Solid Films, vol. 555, pp. 131-137, March 2014.

It has also been reported that the bandgap changes with substrate temperature. P. Puspharajah, S. Radhakrishna, and A. K. A. Rof, “Transparent conducting lithium-doped nickel oxide thin films by spray pyrolysis technique,” 1997.

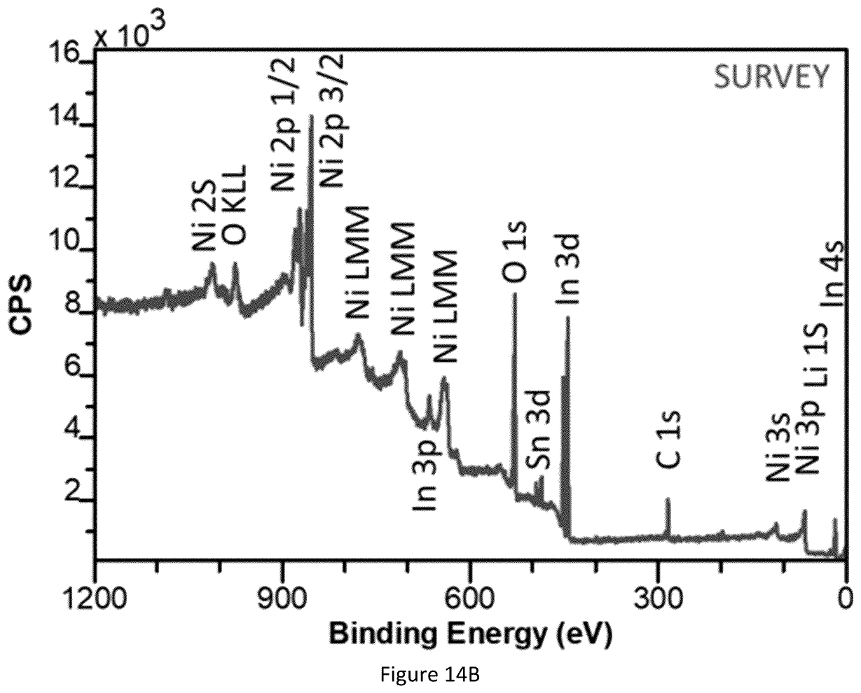

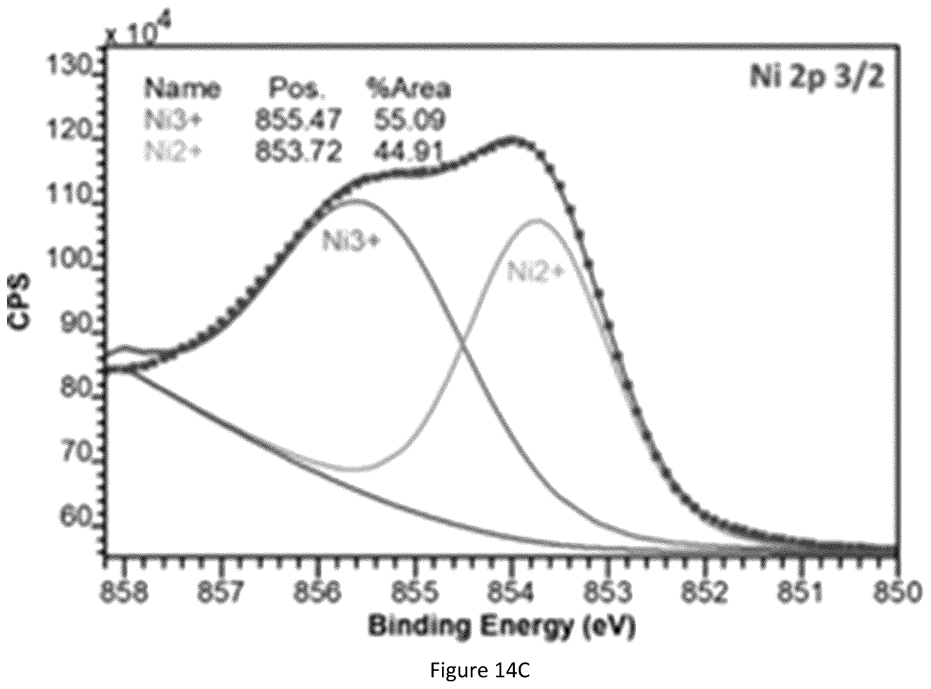

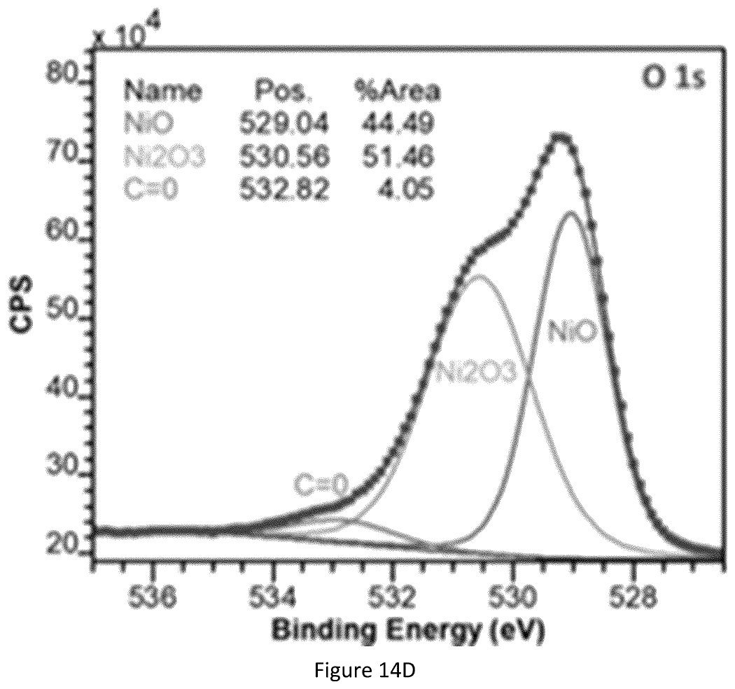

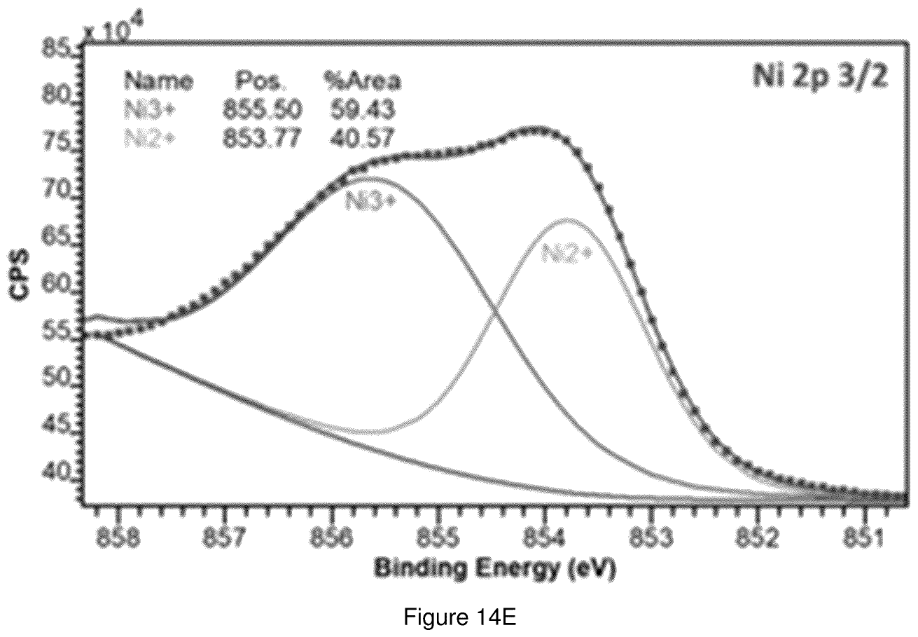

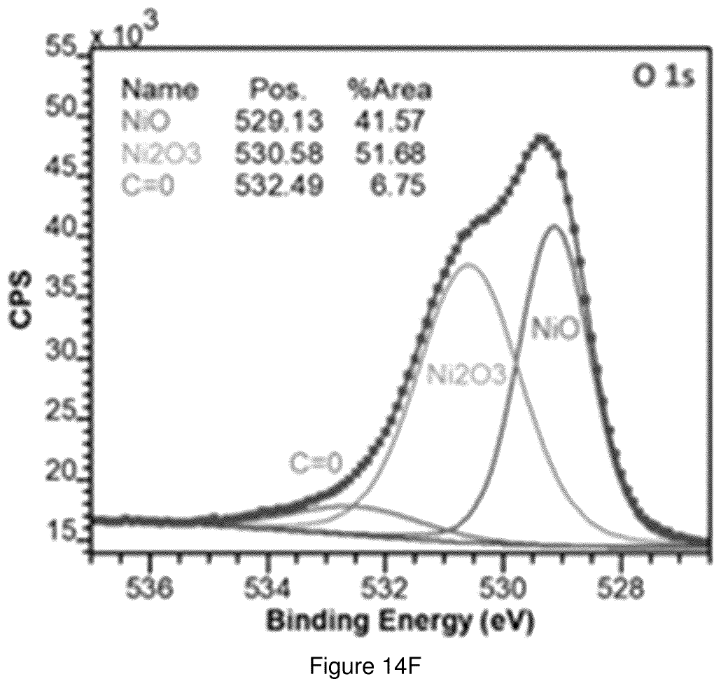

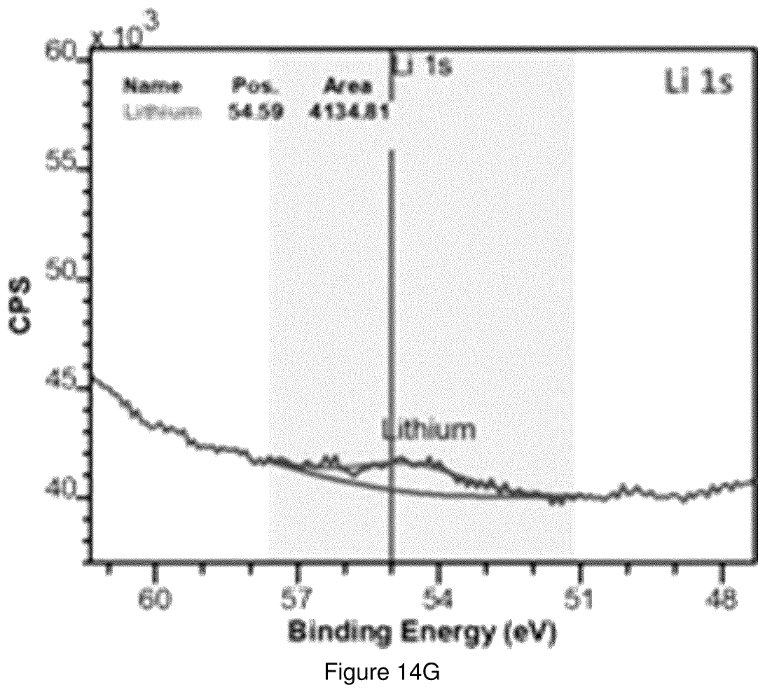

The composition of the film is verified by X-ray photoelectron spectroscopy (“XPS”) on the NiO_{X} film with 8% (mol) Li concentration, i.e., NiO:Li_{0.08}. The XPS peaks are shown FIGS. 14A-14F. Note that the nickel: oxygen ratio is non-stoichiometric, and therefore the lithium molar ratio is with respect to the nickel.

Electrical conductivity was measured by sandwiching the film between ITO and a high work function gold (Au) electrode. The resistivity reduced after increasing the Li concentration to 2% (mol) but after that it stays relatively stable till 8% (mol), after which it increased slightly at 10% (mol).

The perovskite film grown on the Li doped NiO_{X} showed significant improvement in the photoluminescence (“PL”) characteristics over pure NiO_{X} film. The PL intensity increased strongly with the perovskite layer on NiO_{X}/glass substrate compared to bare glass. It further stepped up with addition of Li at 2% (mol). Beyond that the PL increased gradually with the increase in Li up to 8% (mol), after which it decreased at 10% (mol) Li. This result shows that the presence of Li in NiO_{X} helped to improve the radiative recombination in perovskite film most likely by Li diffusion into the perovskite and passivating the dangling bonds. There was a slight red shift as the Li doping increased. This is attributed to the intercalation of Li into the perovskite structure.

The crystallographic structure of perovskite grown on top of NiO_{X} with varying Li concentration is studied using grazing incidence X-ray diffraction (GIXRD). It is found that the peaks are strongest at 8% Li concentration and fall on either side this sample. It shows that the intercalation of Li also helps in crystal growth to certain extent.

A single junction PSC was made by adding PCBM and ZnO as electron transport layers on top of the perovskite layer, and ending with a silver contact. The SEM cross-section of the device is shown in FIG. 5, which omits the buffer layer(s) of the preferred embodiments.

Comparing the device performance using a box and whiskers plot we can see the improving trend on almost each parameter with the increase in Li doping. The improvement in current density can be directly correlated with the improvement in photoluminescence of the perovskite absorber. More charge carriers undergo radiative recombination, and thus more carriers are collected. The maximum current density extracted increased from 19.4 to 24.4 mA/cm² with Li concentration up to 8% (mol). At 10% (mol), it is reduced due to decrease in transmittance through it and reduced PL seen in the perovskite at 10% (mol) Li.

Open circuit voltage (V_{oc}) also improved up to 6% Li, reaching a maximum of 1.13 V. It stayed at similar levels after that, maintaining an average value greater than 1.05 V. The improvement in the fill factor (FF) is the most prominent and consistent, which was expected. This comes from the reduction in the series resistance of the device due to the doping of the film with Li. The FF increased gradually from a maximum of 67% for 0% Li to a maximum of 78% at 8% (mol) Li. Beyond that there was a slight decrease indicating 8% (mol) Li as an optimal composition.

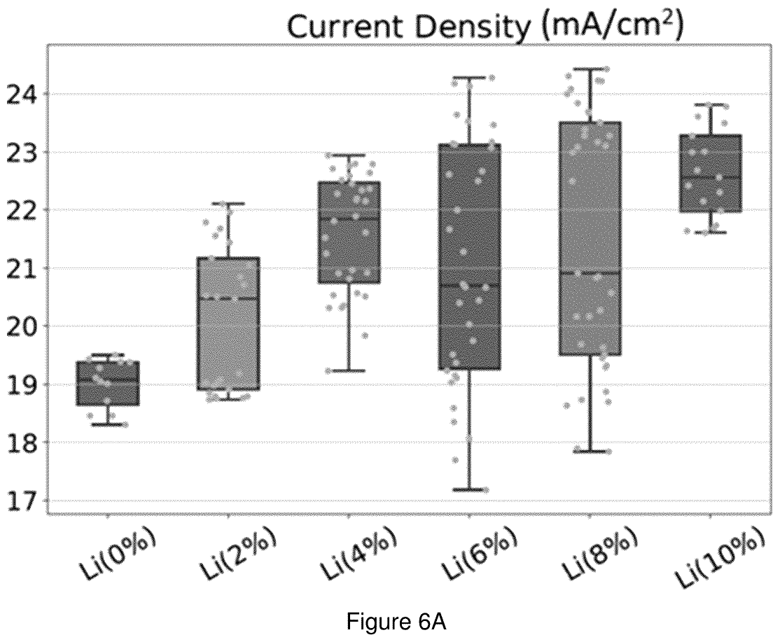

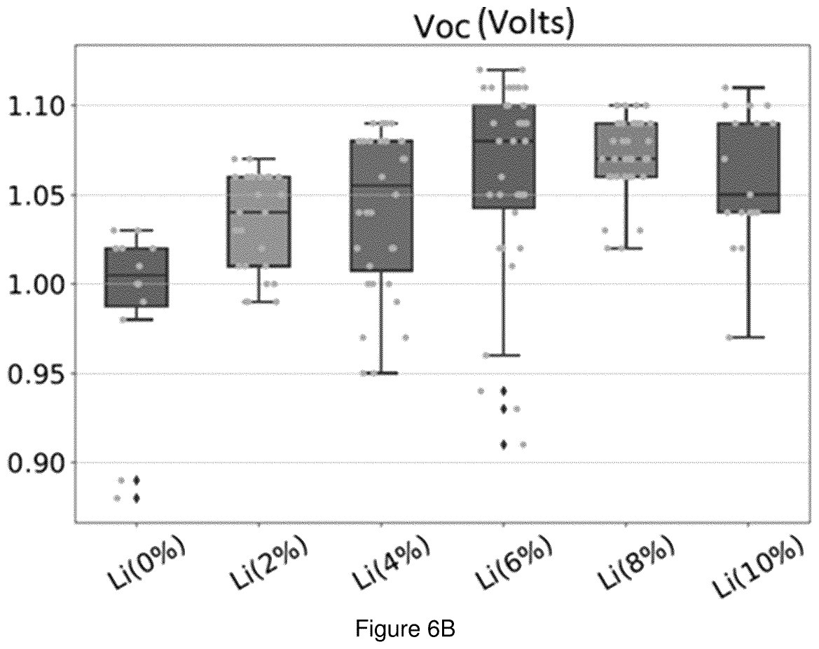

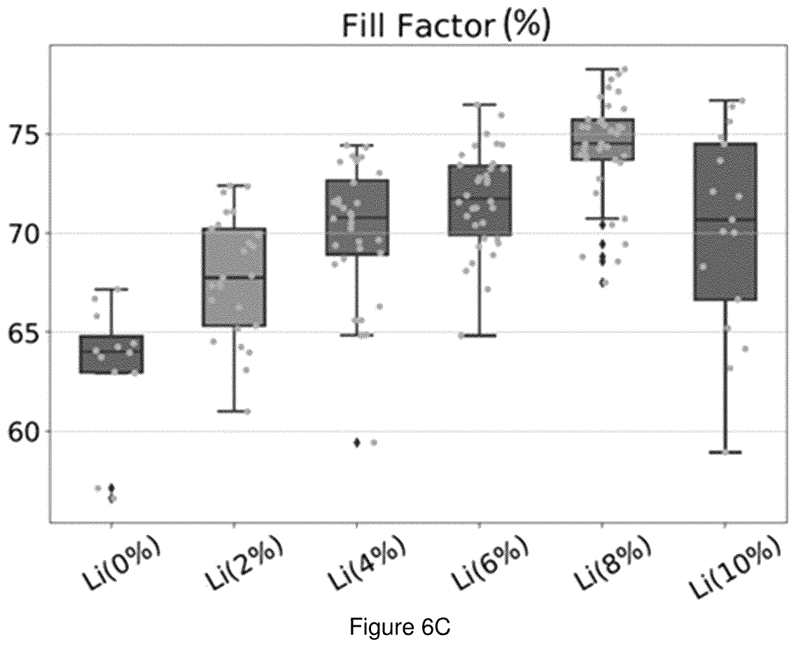

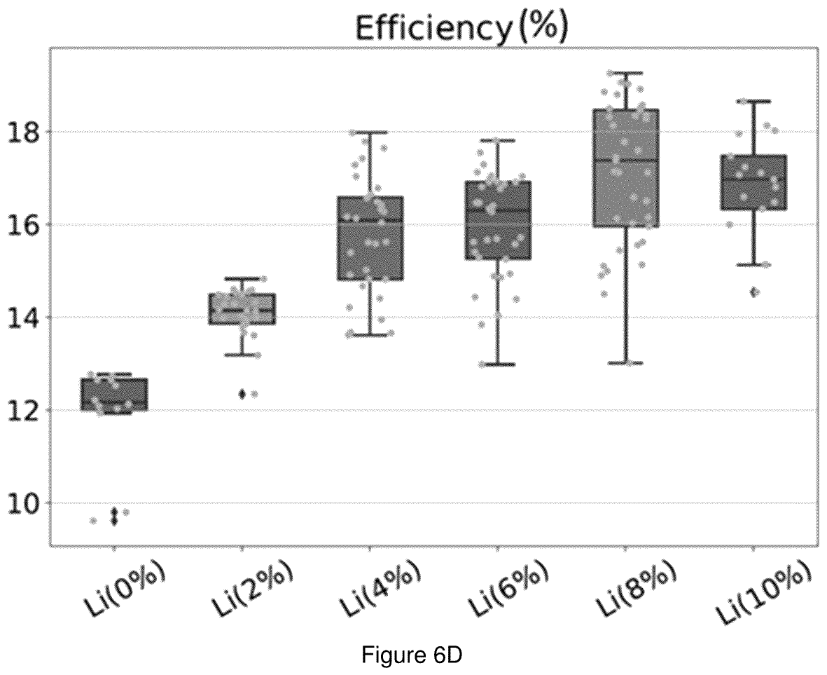

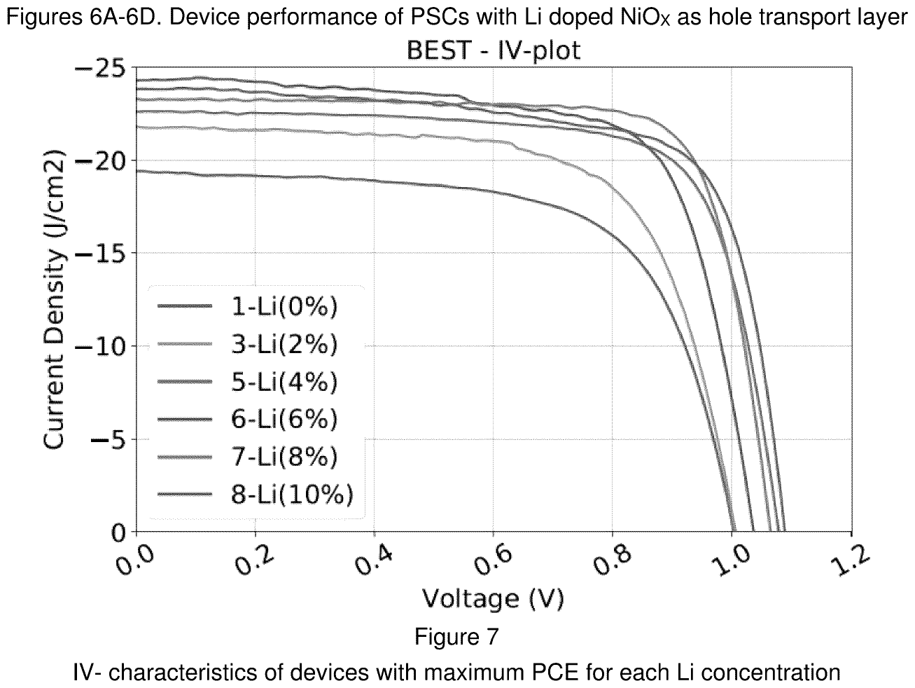

FIGS. 6A-6D show device performance of PSCs with Li doped NiO_{X} as hole transport layer

FIG. 7 shows IV—characteristics of devices with maximum PCE for each Li concentration.

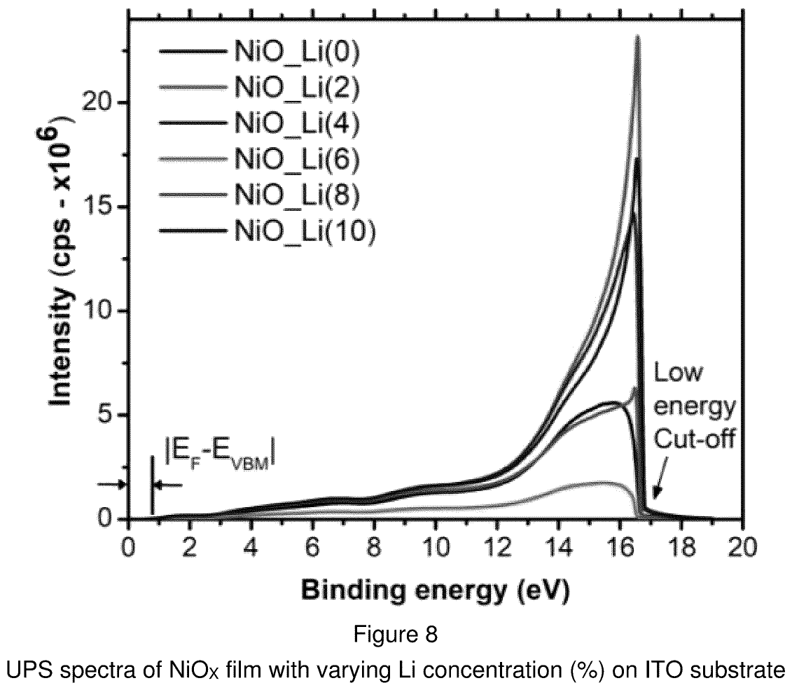

FIG. 8 shows UPS spectra of NiO_{X} films with varying Li concentration (%) on ITO substrate

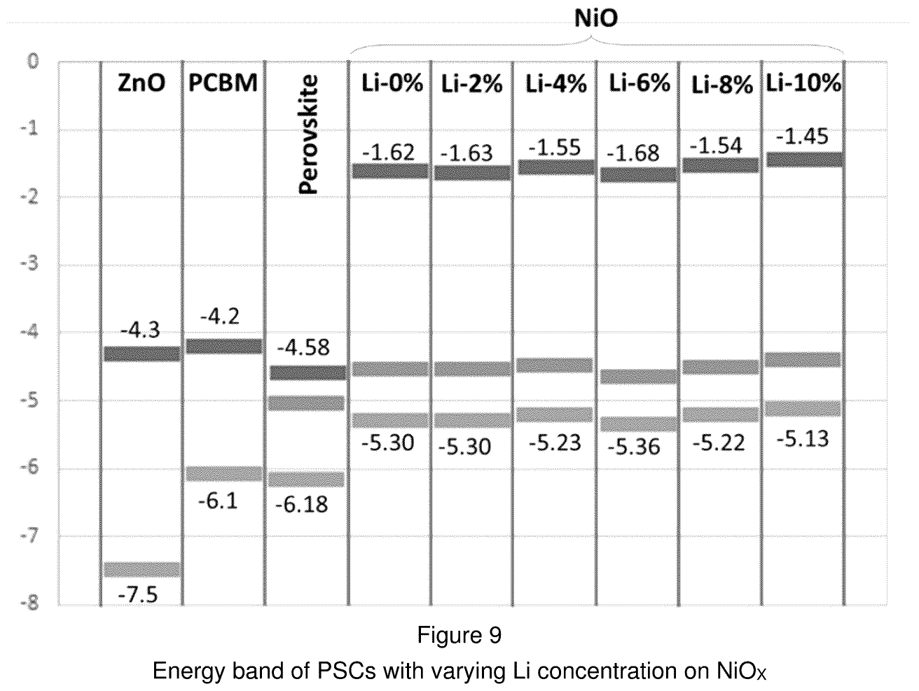

FIG. 9 shows energy band of PSCs with varying Li concentration on NiO_{X}.

Almost all parameters improved up to 8% (mol) Li concentration which is well reflected in the power conversion efficiency of the devices. With this aggregate effect, the PCE improved from ˜12% with 0% Li to a maximum of 19.3% at 8% (mol) Li. The current-voltage (I-V) characteristics of devices with maximum PCE for each Li concentration is shown in FIG. 7.

The influence of Li on the energy band is studied by obtaining the energy band information from Ultra-violet Photoemission Spectroscopy (“UPS”) studies. UPS provides the work-function and the position of valance band maximum with reference to the fermi level as shown in FIG. 8. This information, along with the optical bandgap from the tauc plot, is used to plot an energy band diagram, which is shown in the FIG. 9. The values for ZnO and PCBM are placed according to literature values. See, S. Chatterjee and A. J. Pal, “Introducing Cu 2 O Thin Films as a Hole-Transport Layer in Efficient Planar Perovskite Solar Cell Structures.”; C.-G. Wu, C.-H. Chiang, Z.-L. Tseng, M. K. Nazeeruddin, A. Hagfeldt, and M. Grä, “High efficiency stable inverted perovskite solar cells without current hysteresis,” Energy Environ. Sci. Energy Environ. Sci, vol. 8, no. 8, pp. 2725-2733, 2015.

No significant alteration in energy band position is found. The optical band gap for all compositions remained essentially the same. The position of the valence band maximum (“VBM”) with respect to the fermi level is also essentially same, which is concomitant with the resistivity change as a function of the Li concentration. Thus, the change in energy level in the conduction band and the valance band position is mainly due to the change in work function of NiO_{X}.

The work function was measured by taking the difference between the UV energy and the low energy cutoff shown in FIG. 8. The work function changed gradually with the change in Li concentration from 4.55 eV to 4.42 eV with a difference of only 0.13 eV. This change might have some influence on V_{oc} of the devices, however a clear translation cannot be depicted.

As shown in FIG. 9, the blue line is the valance band, the orange line is the conduction band, and the gray line is the work function.

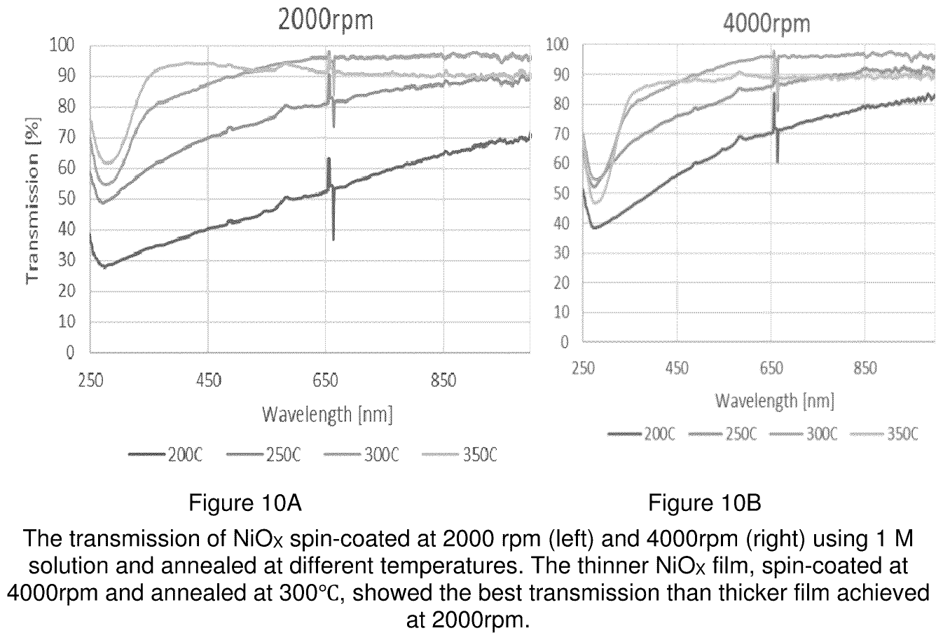

FIGS. 10A and 10B show the transmission of NiO_{X} spin-coated at 2000 rpm (10A) and 4000 rpm (10B) using 1 M solution and annealed at different temperatures. The thinner NiO_{X} film, spin-coated at 4000 rpm and annealed at 300° C., showed the best transmission than thicker film achieved at 2000 rpm.

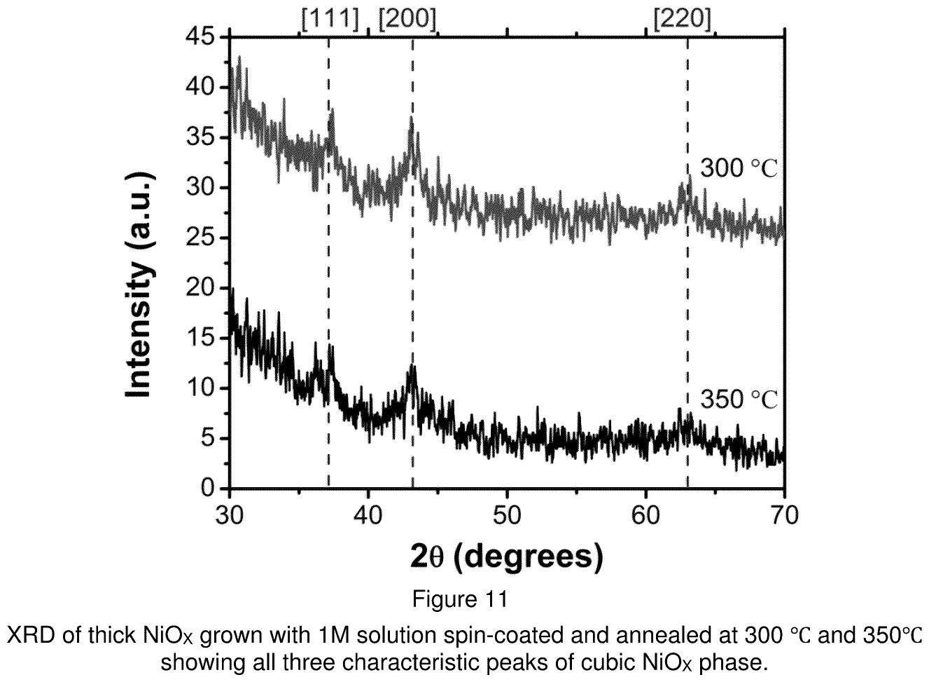

FIG. 11 shows XRD of thick NiO_{X} grown with 1M solution spin-coated and annealed at 300° C. and 350° C. showing all three characteristic peaks of cubic NiO_{X} phase.

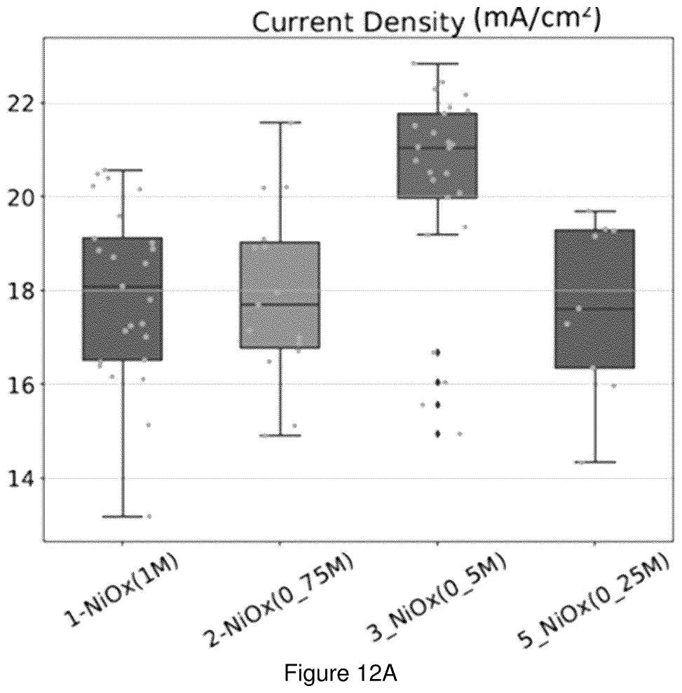

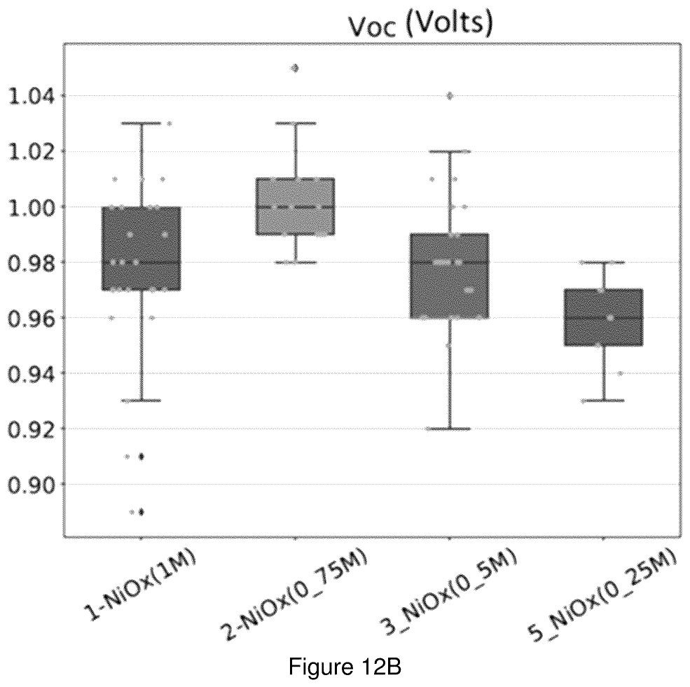

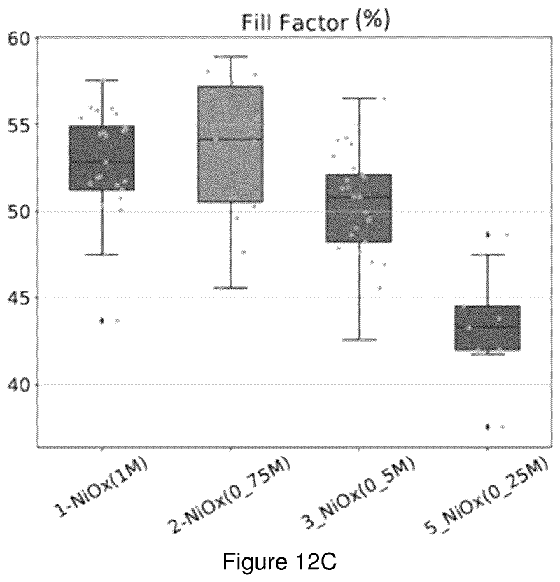

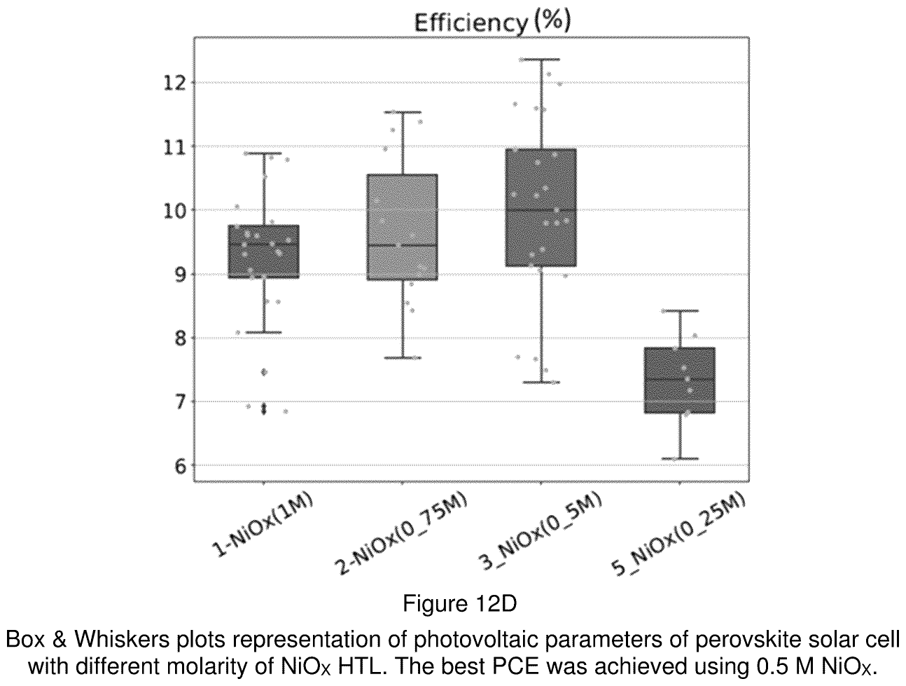

FIGS. 12A to 12D show Box & Whiskers plots representation of photovoltaic parameters of perovskite solar cell with different molarity of NiO_{X} HTL. The best PCE was achieved using 0.5 M NiO_{X}.

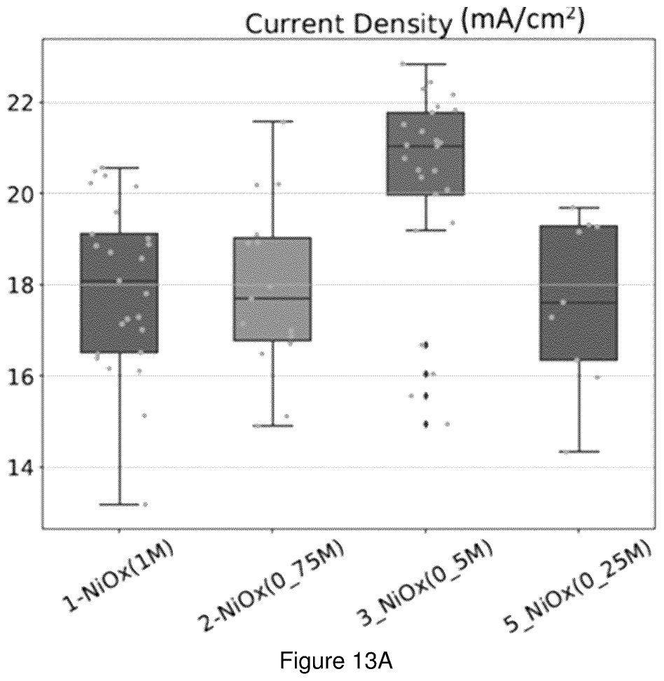

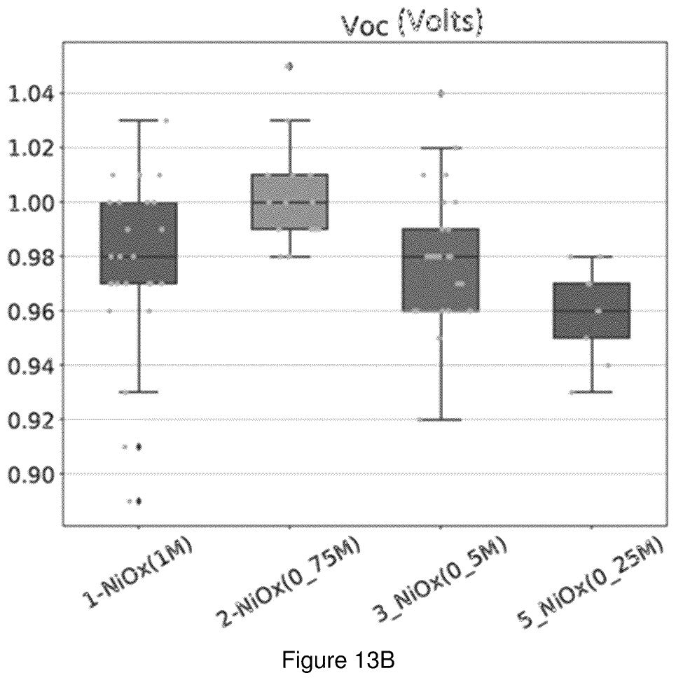

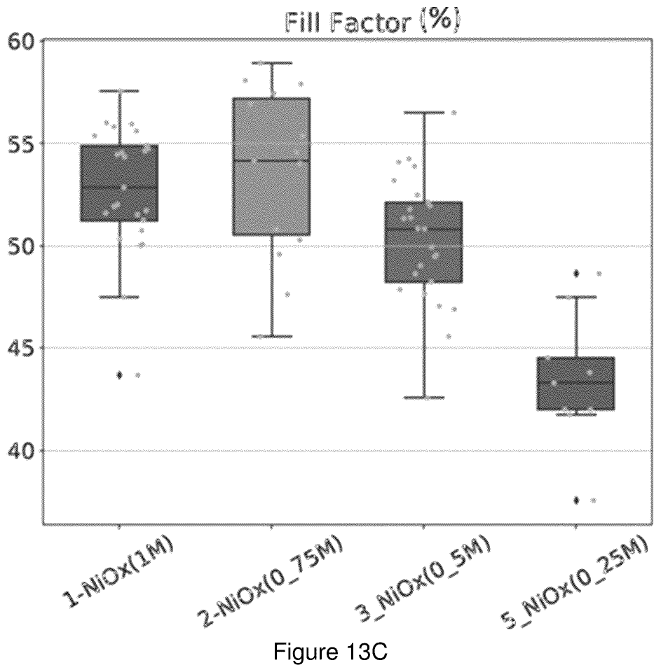

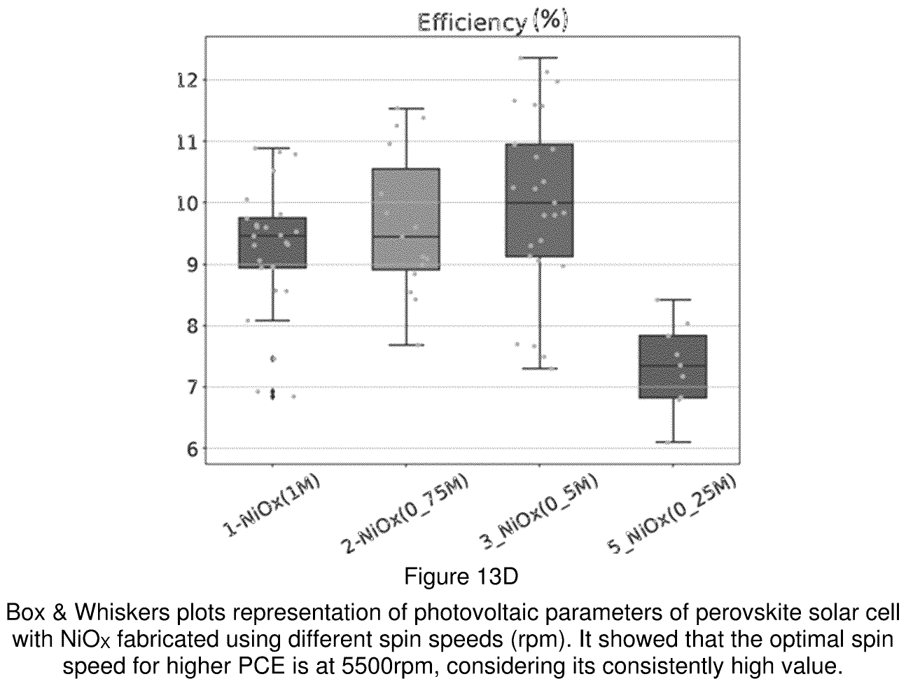

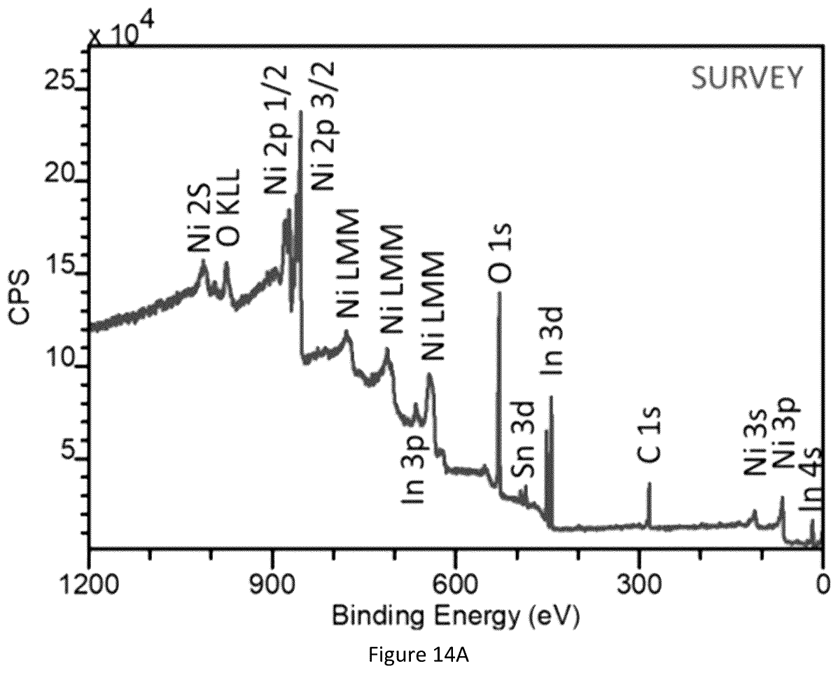

FIGS. 13A to 13D show Box & Whiskers plots representation of photovoltaic parameters of perovskite solar cell with NiO_{X} fabricated using different spin speeds (rpm). It showed that the optimal spin speed for higher PCE is at 5500 rpm, considering its consistently high value.

FIGS. 14A to 14G show XPS comparison of undoped NiO_{X} (left column) and NiO:Li (8%) (right column).

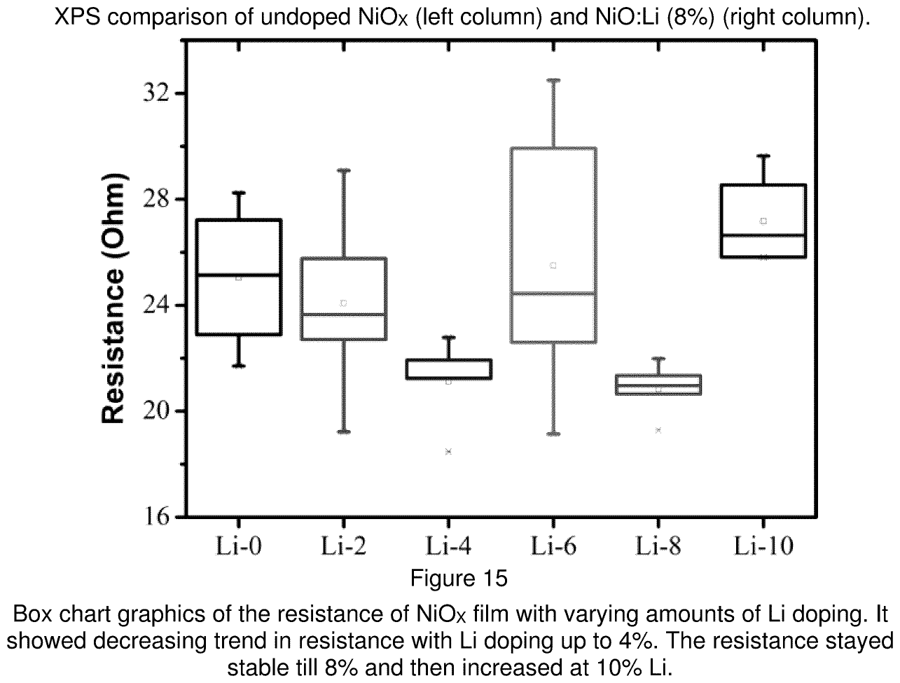

FIG. 15 shows box chart graphics of the resistance of NiO_{X} film with varying amounts of Li doping. It showed a decreasing trend in resistance with Li doping up to 4%. The resistance stayed stable up to 8% Li and then increased over 10% Li.

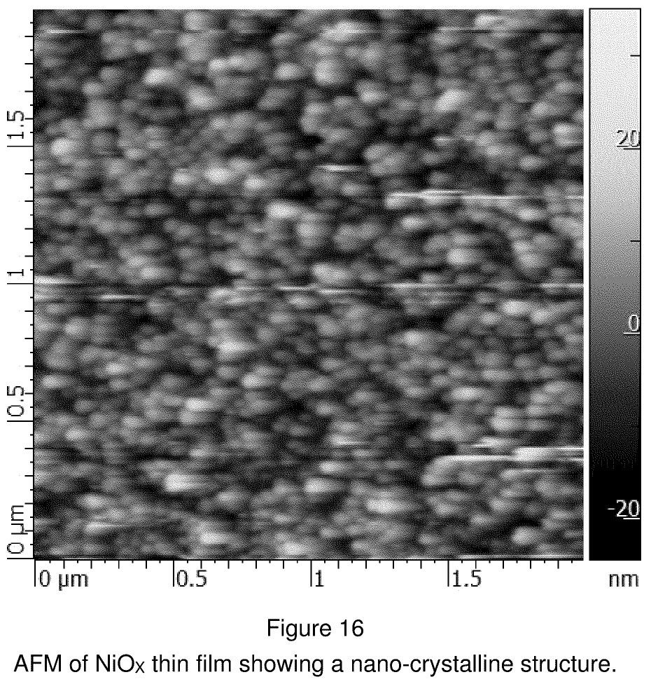

FIG. 16 shows AFM of NiO_{X} thin film showing a nano-crystalline structure.

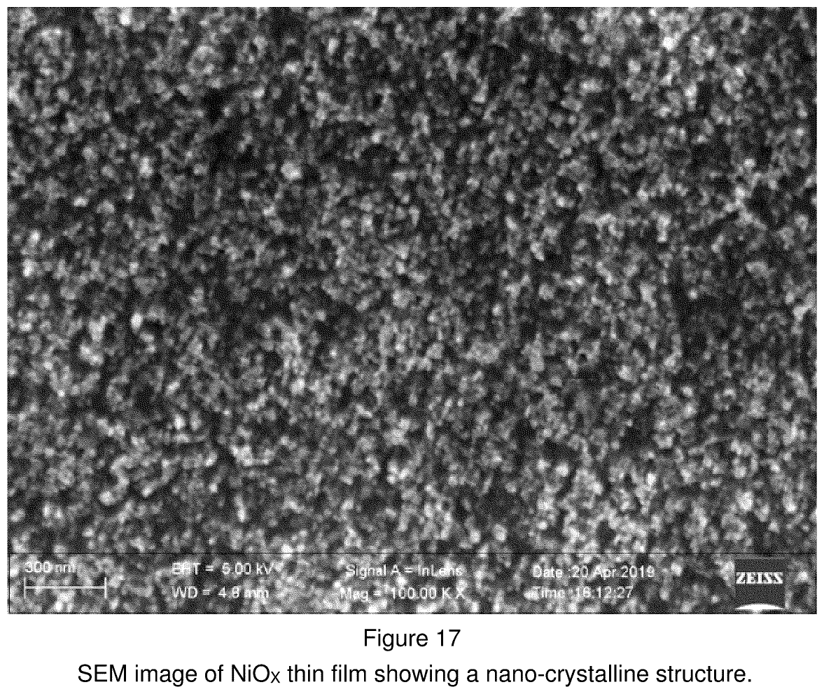

FIG. 17 shows an SEM image of NiO_{X} thin film showing a nano-crystalline structure.

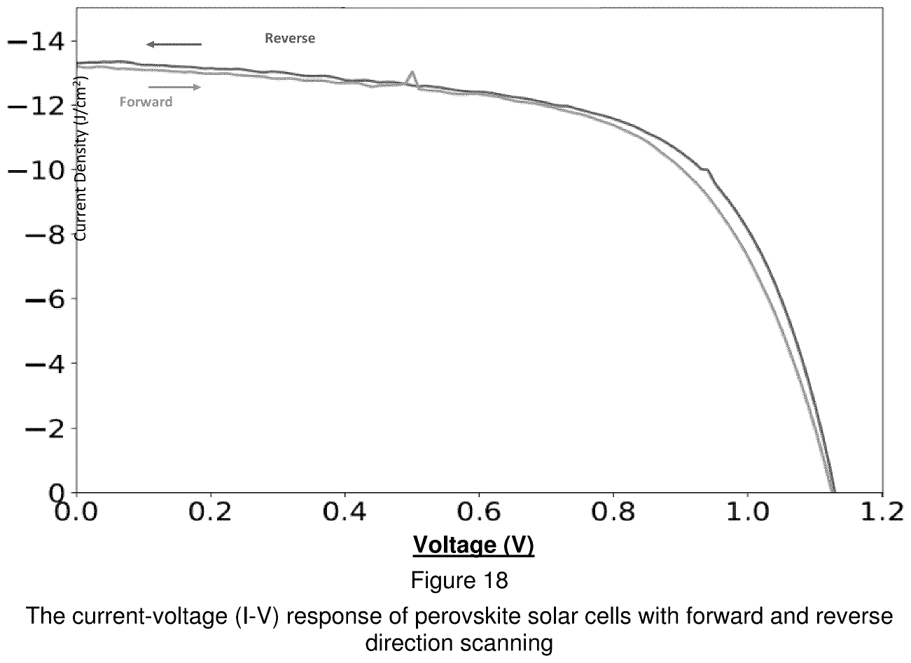

FIG. 18 shows the current-voltage (I-V) response of perovskite solar cells with forward and reverse direction scanning.

It is well known that the Li⁺ ion is the smallest ion after hydrogen and thus has a high diffusion tendency. The ionic mobility of Li⁺ in the perovskite is expected to be higher than that of the intrinsic ions, given its smaller size. The migration of Li⁺ through perovskite materials has been demonstrated by using Methyl-ammonium Lead Iodide (MAPbI₃) perovskites as anode materials in Li-ion batteries. H.-R. Xia, W.-T. Sun, and L.-M. Peng, “Hydrothermal synthesis of organometal halide perovskites for Li-ion batteries” Chem. Commun, vol. 51, p. 13787, 2015.

There are reports showing that ions from perovskites could move into the hole or electron transport layers (HTL/ETLs), enhance carrier-extraction ability, and reduce interface recombination, leading to reduced hysteresis. Z. Li et al., “Extrinsic ion migration in perovskite solar cells,” 1234 Energy Environ. Sci, vol. 10, p. 1234, 2017.

In this case ions migrate from HTL into the perovskite and improve the absorbers property to support better carrier generation and extraction.

The preferred design has one or more buffer layers between the perovskite and the ETL, which prevent ion migration, and also block hole transport to the ETL.

Hysteresis in PSCs is mostly attributed to the presence of TiO₂ in the normal structure as an ETL, which is not an excellent electron conductor. This hinders the ability to collect the electrons and holes flux on the ETL and HTL at same rate and results in hysteresis. J. Hyuck Heo, H. Ji Han, D. Kim, T. Kyu Ahn, and S. Hyuk Im, “Hysteresis-less inverted CH 3 NH 3 PbI 3 planar perovskite hybrid solar cells with 18.1% power conversion efficiency,” Energy Environ. Sci. Energy Environ. Sci, vol. 8, no. 8, pp. 1602-1608, 1602.

In an inverted structure, PCBM is a very good electron conductor compared to TiO₂ and in conjunction with a ZnO/Al₂O₃ buffer that supports better hole blocking, the overall electron extraction is not hindered, in a configuration with the buffer layers over the ETL, opposite that preferred herein. P. P. Rajbhandari and T. P. Dhakal, “Low temperature ALD growth optimization of ZnO, TiO₂, and Al₂O₃ to be used as a buffer layer in perovskite solar cells,” J. Vac. Sci. Technol. A, vol. 38, no. 3, p. 032406, 2020.

Even though it was aimed to improve the conductivity of intrinsic NiO_{X} and align the energy band to achieve better device performance, the added Li in NiO_{X} rather migrated into the perovskite and in turn improved the device performance by actually improving the perovskite's absorber properties. Unlike in a normal device structure, in the inverted device structure, the Li migration does not contribute to a noticeable change in hysteresis. With the Li intercalation into the perovskite and the improvement in its crystalline and photoluminescence properties, a power conversion efficiency of 19.3% was achieved with 8% Li incorporation into NiO_{X} layer, and the buffer layer over the ETL.

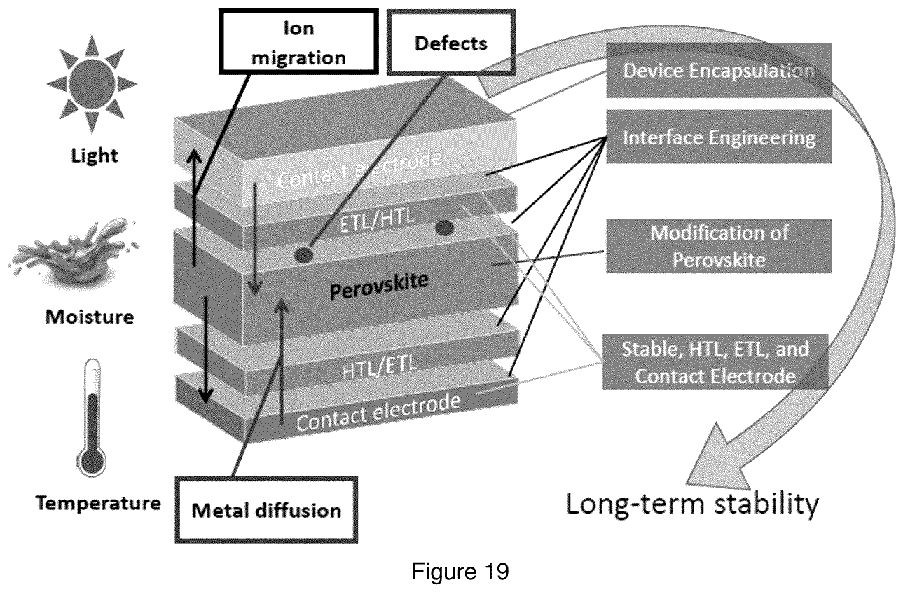

FIG. 19 a traditional PSC and its sources of instability. As represented, light, moisture, heat, ion migration, and defects cause degradation of PSC performance. These sources of instability may be mitigated by device encapsulation, engineering of interfaces (such as by insertion of buffer layers), modification of the perovskite, and selection of HTL, ETL, contact electrode, etc. materials and formation processes.

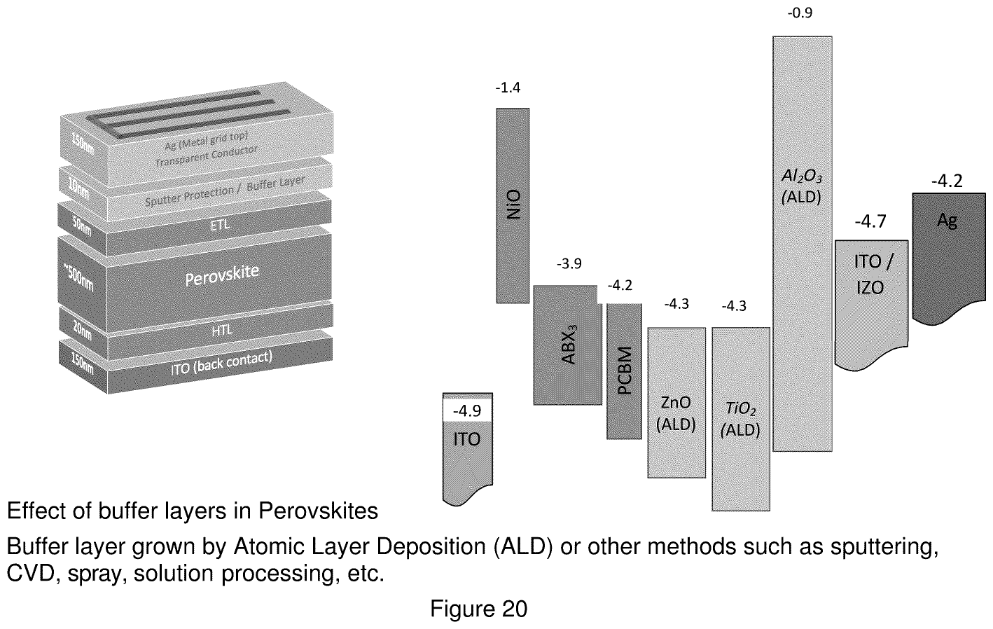

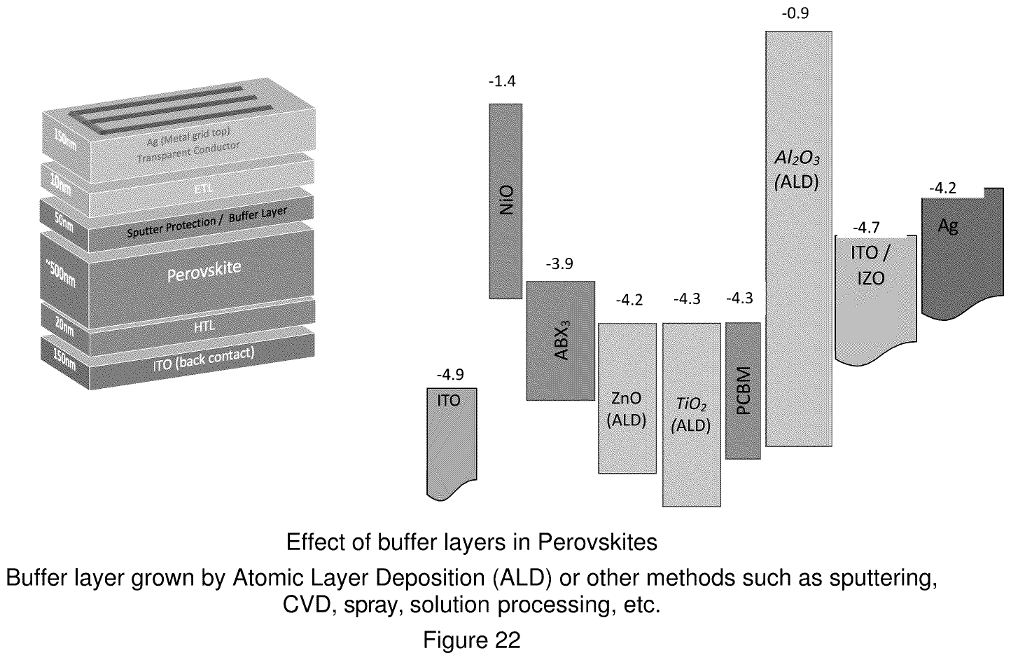

FIGS. 20 and 22 show the effect of buffer layers in Perovskites. As shown in FIG. 20, between the ITO electrode and the silver electrode, are a series of layers, included an inverted p-i-n structure. FIG. 20 shows a buffer layer between the ETL and the conductive electrode (ITO/IZO, Ag). On the other hand, FIG. 22 shows a buffer later between the perovskite layer and the ETL.

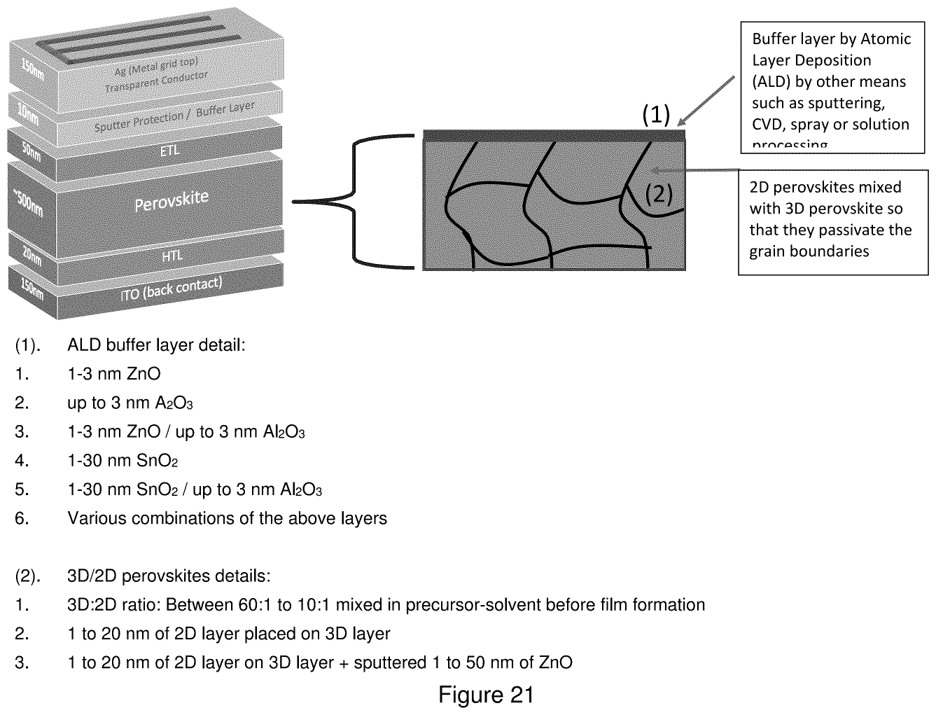

FIG. 21 shows details of the structure of the PSC with the buffer layer over the ETL.

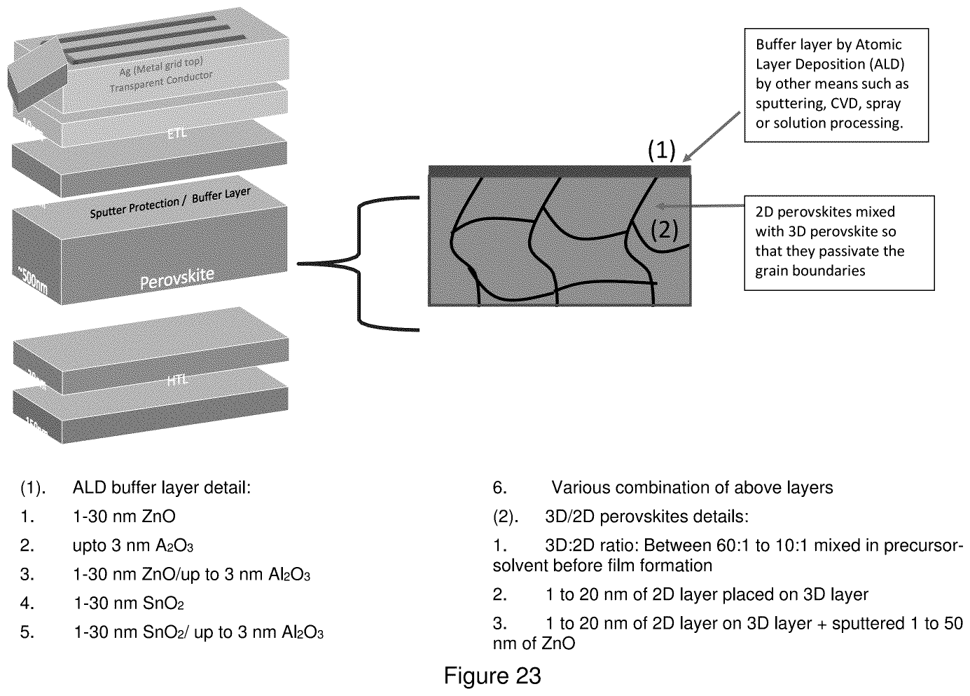

FIG. 23 shows details of the structure of the PSC with the buffer layer over the perovskite and under the ETL.

The disclosure has been described with reference to various specific embodiments and techniques. However, many variations and modifications are possible while remaining within the scope of the disclosure.

### REFERENCES

Each of the following references is hereby expressly incorporated herein by reference in their entirety for all purposes.
H.-R. Xia, W.-T. Sun, and L.-M. Peng, “Hydrothermal synthesis of organometal halide perovskites for Li-ion batteries” ChemComm COMMUNICATION,” Chem. Commun, vol. 51,p. 13787, 2015.
Y.-C. Hsiao, T. Wu, M. Li, Q. Liu, W. Qin, and B. Hu, “Fundamental Physics behind High-Efficiency Organo-Metal Halide Perovskite Solar Cells,” J. Mater. Chem. A, vol. 00, pp. 1-14, 2015.
W.-J. W. Yin, J.-H. J. Yang, J. Kang, Y. Yan, and S.-H. Wei, “Halide perovskite materials for solar cells: a theoretical review,” J. Mater. Chem. A, vol. 3, no. 17, pp. 8926-8942, 2015.
S. Wan-Jian Yin, S.-H. Wei, W.-J. Yin, ab Ji-Hui Yang, J. Kang, and Y. Yan, “Halide Perovskite materials for solar cells: a theoretical review.”
L. Meng, J. You, T.-F. Guo, and Y. Yang, “Recent Advances in the Inverted Planar Structure of Perovskite Solar Cells.”
D. Luo et al., “Enhanced photovoltage for inverted planar heterojunction perovskite solar cells.”
J. Hyuck Heo, H. Ji Han, D. Kim, T. Kyu Ahn, and S. Hyuk Im, “Hysteresis-less inverted CH 3 NH 3 PbI 3 planar perovskite hybrid solar cells with 18.1% power conversion efficiency,” Energy Environ. Sci. Energy Environ. Sci, vol. 8, no. 8, pp. 1602-1608, 1602.
C.-G. Wu, C.-H. Chiang, Z.-L. Tseng, M. K. Nazeeruddin, A. Hagfeldt, and M. Grä, “High efficiency stable inverted perovskite solar cells without current hysteresis,” Energy Environ. Sci. Energy Environ. Sci, vol. 8, no. 8, pp. 2725-2733, 2015.
W. Chen et al., “Efficient and stable large-area perovskite solar cells with inorganic charge extraction layers.”
M. Moniruzzaman Sk, C. Yoon Yue, K. Ghosh, and R. Kumar Jena, “Review on advances in porous nanostructured nickel oxides and their composite electrodes for high-performance supercapacitors,” 2016.
F. Jiang, W. C. H. Choy, X. Li, D. Zhang, and J. Cheng, “Post-treatment-free solution-processed Non-stoichiometric NiO<inf>x</inf> nanoparticles for efficient hole-transport layers of organic optoelectronic devices,” Adv. Mater., vol. 27, no. 18, pp. 2930-2937, 2015.
I. Sta, M. Jlassi, M. Hajji, and H. Ezzaouia, “Structural, optical and electrical properties of undoped and Li-doped NiO thin films prepared by sol-gel spin coating method,” Thin Solid Films, vol. 555, pp. 131-137, March 2014.
D. P. Joseph et al., “Spray deposition and characterization of nanostructured Li doped NiO thin films for application in dye-sensitized solar cells,” IOP Publ. Nanotechnol. Nanotechnol., vol. 19, pp. 485707-10, 2008.
J. H. Park et al., “Efficient CH<inf>3</inf>NH<inf>3</inf>PbI<inf>3</inf>Perovskite Solar Cells Employing Nanostructured p-Type NiO Electrode Formed by a Pulsed Laser Deposition,” Adv. Mater., vol. 27, no. 27, pp. 4013-4019, 2015.
W.-L. Jang, Y.-M. Lu, W.-S. Hwang, and W.-C. Chen, “Electrical properties of Li-doped NiO films,” J. Eur. Ceram. Soc., vol. 30, pp. 503-508, 2010.
S. Oswald and W. Brückner, “XPS depth profile analysis of non-stoichiometric NiO films,” Surf. Interface Anal., vol. 36, no. 1, pp. 17-22, 2004.
P. Puspharajah, S. Radhakrishna, and A. K. A. Rof, “Transparent conducting lithium-doped nickel oxide thin films by spray pyrolysis technique,” 1997.
T. Dutta, P. Gupta, A. Gupta, and J. Narayan, “Effect of Li doping in NiO thin films on its transparent and conducting properties and its application in heteroepitaxial p-n junctions,” J. Appl. Phys. J. Appl. Phys. Appl. Phys. Lett. NiO J. Appl. Phys. Appl. Phys. Lett. Appl. Phys. Lett., vol. 108, no. 10, pp. 83715-13706, 2010.
H. J. Snaith et al., “Anomalous Hysteresis in Perovskite Solar Cells,” J. Phys. Chem. Lett, vol. 5, 2014.
J. A. Dawson et al., “Mechanisms of Lithium Intercalation and Conversion Processes in Organic-Inorganic Halide Perovskites,” 2017.
M. H. Futscher et al., “Quantification of ion migration in CH3NH3PbI3 perovskite solar cells by transient capacitance measurements,” Moritz H. Futscher1, Ju Min Leel, Lucie McGovern1, Loreta A. Muscarella1, Tianyi Wang, 2018.
Z. Xiao et al., “Giant switchable photovoltaic effect in organometal trihalide perovskite devices,” 2015.
E. J. Yoo, M. Lyu, J. H. Yun, C. J. Kang, Y. J. Choi, and L. Wang, “Resistive Switching Behavior in Organic-Inorganic Hybrid CH3NH3PbI3-xClx Perovskite for Resistive Random Access Memory Devices,” Adv. Mater., vol. 27, no. 40, pp. 6170-6175, 2015.
S. Chatterjee and A. J. Pal, “Introducing Cu 2 O Thin Films as a Hole-Transport Layer in Efficient Planar Perovskite Solar Cell Structures.”
Z. Li et al., “Extrinsic ion migration in perovskite solar cells †,” 1234| Energy Environ. Sci, vol. 10, p. 1234, 2017.
P. P. Rajbhandari and T. P. Dhakal, “Low temperature ALD growth optimization of ZnO, TiO 2, and Al 2 O 3 to be used as a buffer layer in perovskite solar cells,” J. Vac. Sci. Technol. A, vol. 38, no. 3, p. 032406, 2020.
P. P. Rajbhandari and T. P. Dhakal, “Limit of incorporating cesium cations into formamidinium-methylammonium based mixed halide perovskite solar cells,” Nanotechnology, vol. 31, p. 135406, 2020.
Stewart R J, Grieco C, Larsen A V, Doucette G S and Asbury J B 2016 Molecular origins of defects in organohalide perovskites and their influence on charge carrier dynamics J. Phys. Chem. C 120 12392-402.
Sahli F and Werner J 2018 Fully textured monolithic perovskite/silicon tandem solar cells with 25.2% power conversion efficiency Nat. Mater. 17 820-6.
Meng L, You J, Yang Y. Addressing the stability issue of perovskite solar cells for commercial applications. Nature communications 2018;9(1) 5265.
Li Z, Zhao Y, Wang X, Sun Y, Zhao Z, Li Y, Zhou H, Chen Q. Cost analysis of perovskite tandem photovoltaics. Joule 2018;2(8):1559-1572.
Liang H, You F. Reshoring silicon photovoltaics manufacturing contributes to decarbonization and climate change mitigation. Nature Communications 2023; 14(1):1274.
Roman MN, Salceanu A, Paulet M, Machidon D. Evaluation upon the Energy Resources of Photovoltaic Systems depending on their Location. 2021 International Conference on Electromechanical and Energy Systems (SIELMEN): IEEE; 2021:253-256.
Fthenakis V, Leccisi E. Updated sustainability status of crystalline silicon-based photovoltaic systems: Life-cycle energy and environmental impact reduction trends. Progress in Photovoltaics: Research and Applications 2021;29(10):1068-1077.
Bhandari KP, Collier JM, Ellingson RJ, Apul DS. Energy payback time (EPBT) and energy return on energy invested (EROI) of solar photovoltaic systems: A systematic review and meta-analysis. Renewable and Sustainable Energy Reviews 2015;47:133-141.
Fthenakis V, Leccisi E. Life-Cycle Analysis of Tandem PV Perovskite-Modules and Systems. 2021 IEEE 48th Photovoltaic Specialists Conference (PVSC): IEEE; 2021:1478-1485.
Rong Y, Hu Y, Mei A, Tan H, Saidaminov MI, Seok SI, McGehee MD, Sargent EH, Han H. Challenges for commercializing perovskite solar cells. Science 2018;361(6408): eaat8235.
Markets and Markets. Perovskite Solar Cell Market. 2022. (SE 8525) (www.marketsandmarkets.com/Market-Reports/perovskite-solar-cell-market-253842189.html).
Seo B, Kim JY, Chung J. Overview of global status and challenges for end-of-life crystalline silicon photovoltaic panels: A focus on environmental impacts. Waste Management 2021;128:45-54.
Irena I-p. End-of-life management: Solar photovoltaic panels. International Renewable Energy Agency and International Energy Agency Photovoltaic Power Systems 2016.
Wu T, Qin Z, Wang Y, Wu Y, Chen W, Zhang S, Cai M, Dai S, Zhang J, Liu J. The main progress of perovskite solar cells in 2020-2021. Nano-Micro Letters 2021;13:1-18.
Crownhart C. Can the most exciting new solar material live up to its hype? MIT Technology Review. (www.technologyreview.com/2021/06/29/1027451/perovskite-solar-panels-hype-commercial-debut/).
Brinkmann KO, Zhao J, Pourdavoud N, Becker T, Hu T, Olthof S, Meerholz K, Hoffmann L, Gahlmann T, Heiderhoff R, Oszajca MF, Luechinger NA, Rogalla D, Chen Y, Cheng B, Riedl T. Suppressed decomposition of organometal halide perovskites by impermeable electron-extraction layers in inverted solar cells. Nature Communications 2017;8(1):13938. DOI: 10.1038/ncomms13938.
Bi E, Chen H, Xie F, Wu Y, Chen W, Su Y, Islam A, Gratzel M, Yang X, Han L. Diffusion engineering of ions and charge carriers for stable efficient perovskite solar cells. Nature Communications 2017;8(1):15330. DOI: 10.1038/ncomms 15330.
NREL, E.C. Photovoltaic Research. www.nrel.gov/pv/(accessed on 31 Dec. 2020).
Lee, B.; Lee, S.; Cho, D.; Kim, J.; Hwang, T.; Kim, K.H.; Hong, S.; Moon, T.; Park, B. Evaluating the Optoelectronic Quality of Hybrid Perovskites by Conductive Atomic Force Microscopy with Noise Spectroscopy. ACS Appl. Mater. Interfaces 2016, 8, 30985-30991.
Kim, J.; Yun, A.J.; Gil, B.; Lee, Y.; Park, B. Triamine-Based Aromatic Cation as a Novel Stabilizer for Efficient Perovskite Solar Cells. Adv. Funct. Mater. 2019, 29, 1905190.
Hwang, T.; Lee, B.; Kim, J.; Lee, S.; Gil, B.; Yun, A.J.; Park, B. Organometal Halide Perovskites: From Nanostructural Evolution to Dynamic Interplay of Constituents: Perspectives for Perovskite Solar Cells. Adv. Mater. 2018, 30, 1704208.
Hwang, T.; Cho, D.; Kim, J.; Kim, J.; Lee, S.; Lee, B.; Kim, K.H.; Hong, S.; Kim, C.; Park, B. Park Investigation of chlorine-mediated microstructural evolution of CH3NH3PbI3(Cl) grains for high optoelectronic responses. Nano Energy 2016, 25, 91-99.
Gunawan, O.; Pac, S.R.; Bishop, D.M.; Lee, Y.S.; Virgus, Y.; Jeon, N.J.; Noh, J.H.; Shao, X.; Todorov, T.; Mitzi, D.B. Carrier-resolved photo hall measurement in world record-quality perovskite and kesterite solar absorbers. Nature 2019, 575, 151-155.
Kim, J.; Hwang, T.; Lee, B.; Lee, S.; Park, K.; Park, H.H.; Park, B. An Aromatic Diamine Molecule as the A-Site Solute for Highly Durable and Efficient Perovskite Solar Cells. Small Methods 2019, 3, 1-6.
Jeon, N.J.; Yang, T.Y.; Park, H.H.; Seo, J.; Nam, D.Y.; Jeong, D.; Hong, S.; Kim, S.H.; Cho, J.M.; Jang, J.J.; et al. Thermally activated, light-induced electronspin-resonance spin density reflected by photocurrents in a perovskite solar cell. Appl. Physics Lett. 2019, 114, 013903.
Kim, M.; Kang, T.-W.; Kim, S.H.; Jung, E.H.; Park, H.H.; Seo, J.; Lee, S.-J. Antireflective, self-cleaning and protective film by continuous sputtering of a plasma polymer on inorganic multilayer for perovskite solar cells application. Sol. Energy Mater. Sol. Cells 2019, 191, 55-61.
Kim, G.; Moon, C.S.; Yang, T.-Y.; Kim, Y.Y.; Chung, J.; Jung, E.H.; Shin, T.J.; Jeon, N.J.; Park, H.H.; Seo, J. A Thermally Induced Perovskite Crystal Control Strategy for Efficient and Photostable Wide-Bandgap Perovskite Solar Cells. Sol. RRL 2020, 4.
Park, H.H.; Larrabee, T.J.; Ruppalt, L.B.; Culbertson, J.C.; Prokes, S.M. Tunable Electrical Properties of Vanadium Oxide by HydrogenPlasma-Treated Atomic Layer Deposition. ACS Omega 2017, 2, 1259-1264.
Park, H.H.; Jayaraman, A.; Heasley, R.; Yang, C.; Hartle, L.; Mankad, R.; Haight, R.; Mitzi, D.B.; Gunawan, O.; Gordon, R.G. Atomic layer deposition of Al-incorporated Zn(O,S) thin films with tunable electrical properties. Appl. Phys. Lett. 2014, 105, 202101.
Hejin Park, H.; Heasley, R.; Gordon, R.G. Atomic layer deposition of Zn(O,S) thin films with tunable electrical properties by oxygen annealing. Appl. Phys. Lett. 2013, 102, 132110.
Raiford, J.A.; Oyakhire, S.T.; Bent, S.F. Applications of atomic layer deposition and chemical vapor deposition for perovskite solar cells. Energy Environ. Sci. 2020, 13, 1997-2023.
Seo, S.; Jeong, S.; Park, H.; Shin, H.; Park, N.-G. Atomic layer deposition for efficient and stable perovskite solar cells. Chem. Commun. 2019, 55, 2403-2416.
Oviroh, P.O.; Akbarzadeh, R.; Pan, D.; Coetzee RA, M.; Jen, T.C. New development of atomic layer deposition: Processes, methods and applications. Sci. Technol. Adv. Mater. 2019, 20, 465-496.
Hoye, R.; Muñoz-Rojas, D.; Nelson, S.F.; Illiberi, A.; Poodt, P.; Roozeboom, F.F.; MacManus-Driscoll, J.L. Research Update: Atmospheric pressure spatial atomic layer deposition of ZnO thin films: Reactors, doping, and devices. APL Mater. 2015, 3, 040701.
Steinmann, V.; Jaramillo, R.; Hartman, K.; Chakraborty, R.; Brandt, R.E.; Poindexter, J.R.; Lee, Y.S.; Sun, L.; Polizzotti, A.; Park, H.H.; et al. Buonassisi, 3.88% Efficient Tin Sulfide Solar Cells using Congruent Thermal Evaporation. Adv. Mater. 2014, 26, 7488-7492.
Kim, D.; Jung, H.J.; Park, I.J.; Larson, B.W.; Dunfield, S.P.; Xiao, C.; Kim, J.; Tong, J.; Boonmongkolras, P.; Ji, S.G.; et al. Efficient, stable silicon tandem cells enabled by anion-engineered wide-bandgap perovskites. Science 2020, 368, 155-160.
Lim, J.; Kim, M.; Park, H.H.; Jung, H.; Lim, S.; Hao, X.; Choi, E.; Park, S.; Lee, M.; Liu, Z.; et al. Kinetics of light-induced degradation in semi-transparent perovskite solar cells. Sol. Energy Mater. Sol. Cells 2021, 219, 110776.
Lee, B.; Shin, B.; Park, B. Uniform Cs2SnI6 Thin Films for Lead-Free and Stable Perovskite Optoelectronics via Hybrid Deposition Approaches. Electron. Mater. Lett. 2019, 15, 192-200.
Todorov, T.; Gunawan, O.; Guha, S. A road towards 25% efficiency and beyond: Perovskite tandem solar cells. Mol. Syst. Des. Eng. 2016, 1, 370-376.
Yun, A.J.; Kim, J.; Hwang, T.; Park, B. Origins of Efficient Perovskite Solar Cells with Low-Temperature Processed SnO2 Electron Transport Layer. ACS Appl. Energy Mater. 2019, 2, 3554-3560.
Correa-Baena, J.-P.; Tress, W.; Domanski, K.; Anaraki, E.H.; Cruz, S.H.T.; Roose, B.; Boix, P.P.; Grätzel, M.; Saliba, M.; Abate, A.; et al. Identifying and suppressing interfacial recombination to achieve high open-circuit voltage in perovskite solar cells. Energy Environ. Sci. 2017, 10, 1207-1212.
Wang, C.; Xiao, C.; Yu, Y.; Zhao, D.; Awni, R.A.; Grice, C.R.; Ghimire, K.; Constantinou, I.; Liao, W.; Cimaroli, A.J.; et al. Understanding and Eliminating Hysteresis for Highly Efficient Planar Perovskite Solar Cells. Adv. Energy Mater. 2017, 7.
Zhang, J.; Chen, Y.; Guo, W. Optimizing the efficiency of perovskite solar cells by a sub-nanometer compact titanium oxide electron transport layer. Nano Energy 2018, 49, 230-236.
Lu, H.; Ma, Y.; Gu, B.; Tian, W.; Li, L. Identifying the optimum thickness of electron transport layers for highly efficient perovskite planar solar cells. J. Mater. Chem. A 2015, 3, 16445-16452.
Sun, H.; Deng, K.; Zhu, Y.; Liao, M.; Xiong, J.; Li, Y.; Li, L. A Novel Conductive Mesoporous Layer with a Dynamic Two-Step Deposition Strategy Boosts Efficiency of Perovskite Solar Cells to 20%. Adv. Mater. 2018, 30, e1801935.
Chavan, R.D.; Yadav, P.; Tavakoli, M.M.; Prochowicz, D.; Nimbalkar, A.; Bhoite, S.P.; Bhosale, P.N.; Hong, C.K. Double layer mesoscopic electron contact for efficient perovskite solar cells. Sustain. Energy Fuels 2020, 4, 843-851.
Wei, H.; Wu, J.; Qiu, P.; Liu, S.; He, Y.; Peng, M.; Li, D.; Meng, Q.; Zaera, F.; Zheng, X. Plasma-enhanced atomic-layer-deposited gallium nitride as an electron transport layer for planar perovskite solar cells. J. Mater. Chem. A 2019, 7, 25347-25354.
Correa-Baena, J.-P.; Steier, L.; Tress, W.; Saliba, M.; Neutzner, S.; Matsui, T.; Giordano, F.; Jacobsson, T.J.; Kandada, A.R.S.; Zakeeruddin, S.M.; et al. Highly efficient planar perovskite solar cells through band alignment engineering. Energy Environ. Sci. 2015, 8, 2928-2934.
Lee, Y.; Lee, S.; Seo, G.; Paek, S.; Cho, K.T.; Huckaba, A.J.; Calizzi, M.; Choi, D.-W.; Park, J.-S.; Lee, D.; et al. Efficient Planar Perovskite Solar Cells Using Passivated Tin Oxide as an Electron Transport Layer. Adv. Sci. 2018, 5, 1800130.
Wang, C.; Guan, L.; Zhao, D.; Yu, Y.; Grice, C.R.; Song, Z.; Awni, R.A.; Chen, J.; Wang, J.; Zhao, X.; et al. Water Vapor Treatment of Low-Temperature Deposited SnO2 Electron Selective Layers for Efficient Flexible Perovskite Solar Cells. ACS Energy Lett. 2017, 2, 2118-2124.
Wang, C.; Zhao, D.; Grice, C.R.; Liao, W.; Yu, Y.; Cimaroli, A.; Shrestha, N.; Roland, P.J.; Chen, J.; Yu, Z.; et al. Low-temperature plasma-enhanced atomic layer deposition of tin oxide electron selective layers for highly efficient planar perovskite solar cells. J. Mater. Chem. A 2016, 4, 12080-12087.
Li, W.; Dong, H.; Guo, X.; Li, N.; Li, J.; Niu, G.; Wang, L. Graphene oxide as dual functional interface modifier for improving wettability and retarding recombination in hybrid perovskite solar cells. J. Mater. Chem. A 2014, 2, 20105-20111.
Zhu, W.; Su, A.; Li, X.; Pang, S.; Chang, J.; Xi, H.; Zhang, C.; Zhang, J.; Zhang, C.; Hao, Y. Efficient planar perovskite solar cells with low-temperature atomic layer deposited TiO2 electron transport layer and interfacial modifier. Sol. Energy 2019, 188, 239-246.
Kim, T.W.; Uchida, S.; Kondo, T.; Segawa, H. Optimization of TiO2 compact layer formed by atomic layer deposition for efficient perovskite solar cells. Appl. Phys. Lett. 2019, 115, 203902.
Chandiran, A.K.; Yella, A.; Mayer, M.T.; Gao, P.; Nazeeruddin, M.K.; Grätzel, M. Sub-Nanometer Conformal TiO 2 Blocking Layer for High Effi ciency Solid-State Perovskite Absorber Solar Cells. Adv. Mater. 2014, 26, 4309-4312.
Zardetto, V.; Di Giacomo, F.; Lifka, H.; Verheijen, M.A.; Weijtens, C.H.L.; Black, L.E.; Veenstra, S.; Kessels, W.M.M.; Andriessen, R.; Creatore, M. Surface Fluorination of ALD TiO2 Electron Transport Layer for Efficient Planar Perovskite Solar Cells. Adv. Mater. Interfaces 2018, 5.
Jin, T.Y.; Li, W.; Li, Y.Q.; Luo, Y.X.; Shen, Y.; Cheng, L.P.; Tang, J.X. High-Performance Flexible Perovskite Solar Cells Enabled by Low-Temperature ALD-Assisted Surface Passivation. Adv. Optical Mater. 2018, 6, 1801153.
Mali, S.S.; Shim, C.-S.; Park, H.K.; Heo, J.; Patil, P.S.; Hong, C.K. Ultrathin Atomic Layer Deposited TiO2 for Surface Passivation of Hydrothermally Grown 1D TiO2 Nanorod Arrays for Efficient Solid-State Perovskite Solar Cells. Chem. Mater. 2015, 27, 1541-1551.
Chavan, R.D.; Tavakoli, M.M.; Prochowicz, D.; Yadav, P.; Lote, S.S.; Bhoite, S.P.; Nimbalkar, A.; Hong, C.K. Atomic Layer Deposition of an Effective Interface Layer of TiN for Efficient and Hysteresis-Free Mesoscopic Perovskite Solar Cells. ACS Appl. Mater. Interfaces 2020, 12, 8098-8106.
Tan, W.; Hendricks, O.L.; Meng, A.C.; Braun, M.R.; McGehee, M.D.; Chidsey, C.E.; McIntyre, P.C. Atomic Layer Deposited TiO2—IrOx Alloy as a Hole Transport Material for Perovskite Solar Cells. Adv. Mater. Interfaces 2018, 5, 1800191.
Cao, B.; Yang, L.; Jiang, S.; Lin, H.; Wang, N.; Li, X. Flexible quintuple cation perovskite solar cells with high efficiency. J. Mater. Chem. A 2019, 7, 4960-4970.
Zhao, B.; Lee, L.C.; Yang, L.; Pearson, A.J.; Lu, H.; She, X.-J.; Cui, L.; Zhang, K.H.L.; Hoye, R.L.Z.; Karani, A.; et al. In Situ Atmospheric Deposition of Ultrasmooth Nickel Oxide for Efficient Perovskite Solar Cells. ACS Appl. Mater. Interfaces 2018, 10, 41849-41854.
Koushik, D.; Jošt, M.; Dučinskas, A.; Burgess, C.; Zardetto, V.; Weijtens, C.; Verheijen, M.A.; Kessels, W.M.M.; Albrecht, S.; Creatore, M. Plasma-assisted atomic layer deposition of nickel oxide as hole transport layer for hybrid perovskite solar cells. J. Mater. Chem. C 2019, 7, 12532-12543.
Seo, S.; Jeong, S.; Bae, C.; Park, N.-G.; Shin, H. Perovskite Solar Cells with Inorganic Electron-and Hole-Transport Layers Exhibiting Long-Term (≈500 h) Stability at 85° C. under Continuous 1 Sun Illumination in Ambient Air. Adv. Mater. 2018, 30, e1801010.
Chu, S.; Zhao, R.; Liu, R.; Gao, Y.; Wang, X.; Liu, C.; Chen, J.; Zhou, H. Atomic-layer-deposited ultra-thin VOx film as a hole transport layer for perovskite solar cells. Semicond. Sci. Technol. 2018, 33, 115016.
Si, H.; Liao, Q.; Zhang, Z.; Li, Y.; Yang, X.; Zhang, G.; Kang, Z.; Zhang, Y. An innovative design of perovskite solar cells with Al 2 O 3 inserting at ZnO/perovskite interface for improving the performance and stability. Nano Energy 2016, 22, 223-231.
Kim, J.; Lee, Y.; Yun, A.J.; Gil, B.; Park, B. Interfacial Modification and Defect Passivation by the Cross-Linking Interlayer for Efficient and Stable CuSCN-Based Perovskite Solar Cells. ACS Appl. Mater. Interfaces 2019, 11, 46818-46824.
Gil, B.; Yun, A.J.; Lee, Y.; Kim, J.; Lee, B.; Park, B. Recent Progress in Inorganic Hole Transport Materials for Efficient and Stable Perovskite Solar Cells. Electron. Mater. Lett. 2019, 15, 505-524.
Gil, B.; Kim, J.; Yun, A.J.; Park, K.; Cho, J.; Park, M.; Park, B. CuCrO2 Nanoparticles Incorporated into PTAA as a Hole Transport Layer for 85° C. and Light Stabilities in Perovskite Solar Cells. Nanomaterials 2020, 10, 1669.
Kim, I.S.; Martinson, A.B.F. Stabilizing hybrid perovskites against moisture and temperature via non-hydrolytic atomic layer deposited overlayers. J. Mater. Chem. A 2015, 3, 20092-20096.
Zardetto, V.V.; Ben Williams, B.; Perrotta, A.A.; Di Giacomo, F.; Verheijen, M.M.; Andriessen, R.; Kessels, W.M.M.; Creatore, M. Atomic layer deposition for perovskite solar cells: Research status, opportunities and challenges. Sustain. Energy Fuels 2017, 1, 30-55.
Koushik, D.; Hazendonk, L.; Zardetto, V.; Vandalon, V.; Verheijen, M.A.; Kessels, W.M.M.; Creatore, M. Chemical Analysis of the Interface between Hybrid Organic—Inorganic Perovskite and Atomic Layer Deposited Al2O3. ACS Appl. Mater. Interfaces 2019, 11, 5526-5535.
Yu, X.; Yan, H.; Peng, Q. Reaction Temperature and Partial Pressure Induced Etching of Methylammonium Lead Iodide Perovskite by Trimethylaluminum. Langmuir 2019, 35, 6522-6531.
Hultqvist, A.; Aitola, K.; Sveinbjörnsson, K.; Saki, Z.; Larsson, F.; Törndahl, T.; Johansson, E.M.J.; Boschloo, G.; Edoff, M. Atomic Layer Deposition of Electron Selective SnOx and ZnO Films on Mixed Halide Perovskite: Compatibility and Performance. ACS Appl. Mater. Interfaces 2017, 9, 29707-29716.
Palmstrom, A.F.; Raiford, J.A.; Prasanna, R.; Bush, K.A.; Sponseller, M.; Cheacharoen, R.; Minichetti, M.C.; Bergsman, D.S.; Leijtens, T.; Wang, H.-P.; et al. Interfacial Effects of Tin Oxide Atomic Layer Deposition in Metal Halide Perovskite Photovoltaics. Adv. Energy Mater. 2018, 8.
Tong, J.; Song, Z.; Kim, D.H.; Chen, X.; Chen, C.; Palmstrom, A.F.; Ndione, P.F.; Reese, M.O.; Dunfield, S.P.; Reid, O.G. Carrier lifetimes of >1 ms in Sn—Pb perovskites enable efficient all-perovskite tandem solar cells. Science 2019, 364, 475-479.
Eom, T.; Kim, S.; Agbenyeke, R.E.; Jung, H.; Shin, S.M.; Lee, Y.K.; Kim, C.G.; Chung, T.; Jeon, N.J.; Park, H.H.; et al. Copper Oxide Buffer Layers by Pulsed-Chemical Vapor Deposition for Semitransparent Perovskite Solar Cells. Adv. Mater. Interfaces 2020, 2020.
Lu, Z.; Wang, S.; Liu, H.; Feng, F.; Li, W. Improved Efficiency of Perovskite Solar Cells by the Interfacial Modification of the Active Layer. Nanomaterials 2019, 9, 204.
Koushik, D.; Verhees, W.J.H.; Kuang, Y.; Veenstra, S.; Zhang, D.; Verheijen, M.A.; Creatore, M.; Schropp, R.E.I. High-efficiency humidity-stable planar perovskite solar cells based on atomic layer architecture. Energy Environ. Sci. 2017, 10, 91-100.
Palmstrom, A.F.; Eperon, G.E.; Leijtens, T.; Prasanna, R.; Habisreutinger, S.N.; Nemeth, W.; Gaulding, E.A.; Dunfield, S.P.; Reese, M.; Nanayakkara, S.; et al. Enabling Flexible All-Perovskite Tandem Solar Cells. Joule 2019, 3, 2193-2204.
Jagt, R.A.; Huq, T.N.; Hill, S.A.; Thway, M.; Liu, T.; Napari, M.; Roose, B.; Gałkowski, K.; Li, W.; Lin, S.F.; et al. Rapid Vapor-Phase Deposition of High-Mobility p-Type Buffer Layers on Perovskite Photovoltaics for Efficient Semitransparent Devices. ACS Energy Lett. 2020, 5, 2456-2465.
Ma, J.; Zheng, M.; Chen, C.; Zhu, Z.; Zheng, X.; Chen, Z.; Guo, Y.; Liu, C.; Yan, Y.; Fang, G. Efficient and Stable Nonfullerene-Graded Heterojunction Inverted Perovskite Solar Cells with Inorganic Ga2 O3 Tunneling Protective Nanolayer. Adv. Funct. Mater. 2018, 28.
Chen, B.; Yu, Z.; Liu, K.; Zheng, X.; Liu, Y.; Shi, J.; Spronk, D.; Rudd, P.N.; Holman, Z.; Huang, J. Grain Engineering for Perovskite/Silicon Monolithic Tandem Solar Cells with Efficiency of 25.4%. Joule 2019, 3, 177-190.
Nogay, G.; Sahli, F.; Werner, J.; Monnard, R.; Boccard, M.; Despeisse, M.; Haug, F.-J.; Jeangros, Q.; Ingenito, A.; Ballif, C. 25.1%-Efficient Monolithic Perovskite/Silicon Tandem Solar Cell Based on a p-type Monocrystalline Textured Silicon Wafer and High-Temperature Passivating Contacts. ACS Energy Lett. 2019, 4, 844-845.
Jošt, M.; Kohnen, E.; Vilches, A.B.M.; Lipovšek, B.; Jäger, K.; Macco, B.; Al-Ashouri, A.; Krč, J.; Korte, L.; Rech, B.; et al. Textured interfaces in monolithic perovskite/silicon tandem solar cells: Advanced light management for improved efficiency and energy yield. Energy Environ. Sci. 2018, 11, 3511-3523.
Kim, D.H.; Muzzillo, C.P.; Tong, J.; Palmstrom, A.F.; Larson, B.W.; Choi, C.; Harvey, S.P.; Glynn, S.; Whitaker, J.B.; Zhang, F.; et al. Bimolecular Additives Improve Wide-BandGap Perovskites for Efficient Tandem Solar Cells with CIGS. Joule 2019, 3, 1734-1745.
Raiford, J.A.; Boyd, C.C.; Palmstrom, A.F.; Wolf, E.J.; Fearon, B.A.; Berry, J.J.; McGehee, M.D.; Bent, S.F. Enhanced Nucleation of Atomic Layer Deposited Contacts Improves Operational Stability of Perovskite Solar Cells in Air. Adv. Energy Mater. 2019, 9.
Lv, Y.; Xu, P.; Ren, G.; Chen, F.; Nan, H.; Liu, R.; Wang, D.; Tan, X.; Liu, X.; Zhang, H.; et al. Low-Temperature Atomic Layer Deposition of Metal Oxide Layers for Perovskite Solar Cells with High Efficiency and Stability under Harsh Environmental Conditions. ACS Appl. Mater. Interfaces 2018, 10, 23928-23937.
Raiford, J.A.; Belisle, R.A.; Bush, K.A.; Prasanna, R.; Palmstrom, A.F.; McGehee, M.D.; Bent, S.F. Atomic layer deposition of vanadium oxide to reduce parasitic absorption and improve stability in n-i-p perovskite solar cells for tandems. Sustain. Energy Fuels 2019, 3, 1517-1525.
Chang, C.-Y.; Lee, K.-T.; Huang, W.-K.; Siao, H.-Y.; Chang, Y.-C. High-Performance, Air-Stable, Low-Temperature Processed Semitransparent Perovskite Solar Cells Enabled by Atomic Layer Deposition. Chem. Mater. 2015, 27, 5122-5130.
Hu, X.; Jiang, X.; Xing, X.; Nian, L.; Liu, X.; Huang, R.; Wang, K.; Yip, H.-L.; Zhou, G. Wide-Bandgap Perovskite Solar Cells With Large Open-Circuit Voltage of 1653 mV Through Interfacial Engineering. Sol. RRL 2018, 2.
Kim, Y.; Lee, W.; Jung, D.R.; Kim, J.; Nam, S.; Kim, H.; Park, B. Optical and electronic properties of post-annealed ZnO: Al thin films. Appl. Phys. Lett. 2010, 96, 171902.
Park, H.H.; Kim, J.; Kim, G.; Jung, H.; Kim, S.; Moon, C.S.; Lee, S.J.; Shin, S.S.; Hao, X.; Yun, J.S.; et al. Transparent Electrodes Consisting of a Surface-Treated Buffer Layer Based on Tungsten Oxide for Semitransparent Perovskite Solar Cells and Four-Terminal Tandem Applications. Small Methods 2020, 4.
Hoye, R.L.; Chua, M.R.; Musselman, K.P.; Li, G.; Lai, M.L.; Tan, Z.K.; Greenham, N.C.; MacManus-Driscoll, J.L.; Friend, R.H.; Credgington, D.C. Enhanced Performance in Fluorene-Free Organometal Halide Perovskite Light-Emitting Diodes using Tunable, Low Electron Affi nity Oxide Electron Injectors. Adv. Mater. 2015, 27, 1414-1419.
Li, W.; Xu, Y.-X.; Wang, D.; Chen, F.; Chen, Z.-K. Inorganic perovskite light emitting diodes with ZnO as the electron transport layer by direct atomic layer deposition. Org. Electron. 2018, 57, 60-67.
Hsu, C.-H.; Chen, K.-T.; Huang, P.-H.; Wu, W.-Y.; Zhang, X.-Y.; Wang, C.; Liang, L.-S.; Gao, P.; Qiu, Y.; Lien, S.-Y.; et al. Effect of Annealing Temperature on Spatial Atomic Layer Deposited Titanium Oxide and Its Application in Perovskite Solar Cells. Nanomaterials 2020, 10, 1322.
Park, H.H.; Heasley, R.; Sun, L.; Steinmann, V.; Jaramillo, R.; Hartman, K.; Chakraborty, R.; Sinsermsuksakul, P.; Chua, D.; Buonassisi, A.; et al. Co-optimization of SnS absorber and Zn(O,S) buffer materials for improved solar cells. Prog. Photovoltaics Res. Appl. 201, 23, 901-908.

1. A perovskite solar cell, comprising:
a lithium-doped nickel oxide hole transport layer;
a perovskite layer configured, on photoexcitation, to generate photoexcited electrons and holes, wherein the holes are selectively transferred to the hole transport layer;
a buffer layer, adjacent to the perovskite layer, formed by atomic layer deposition, configured to conduct the photoexcited electrons from the perovskite layer and to reject holes from the perovskite layer, and mitigate ion migration and water diffusion; and
an electron transport layer, adjacent to the buffer layer, configured to accept electrons from the buffer layer.

2. The perovskite solar cell according to claim 1, wherein the buffer layer is configured to increase a power conversion efficiency and a stability of the perovskite layer with respect to a perovskite solar cell comprising the lithium-doped nickel oxide hole transport layer, the perovskite layer, and the electron transport layer, and lacking the buffer layer.

3. The perovskite solar cell according to claim 1, wherein:
the lithium-doped nickel oxide hole transport layer comprises between 0.1 to 10 mol % lithium, and is disposed on an indium tin oxide conductive layer over a glass substrate; and
the electron transport layer comprises phenyl-C61-butyric-acid-methyl-ester (PCBM).

4. The perovskite solar cell according to claim 1, wherein the buffer layer comprises metal oxide layers of at least one of aluminum oxide (Al₂O₃), zinc oxide (ZnO), tin oxide (SnO), silicon dioxide (SiO₂₋ₓ) and titanium dioxide (TiO₂), deposited by atomic layer deposition to a buffer layer thickness of less than 30 nm, grown on at least one of the perovskite layer and the electron transport layer at temperatures below 150° C., wherein the atomic layer deposition is conducted using a non-aqueous oxygen source.

5. The perovskite solar cell according to claim 4, wherein the metal oxide layers comprises each of aluminum oxide (Al₂O₃), zinc oxide (ZnO), tin oxide (SnO), silicon dioxide (SiO₂₋ₓ) and titanium dioxide (TiO₂) buffer layers, each less than 30 nm thick.

6. The perovskite solar cell according to claim 1, further comprising a substrate having a conductive surface, disposed beneath the lithium-doped nickel oxide hole transport layer, a conductive layer over the electron transport layer, and an encapsulant over the conductive layer.

7. The perovskite solar cell according to claim 6, wherein the encapsulant comprises atomic layer deposition (ALD) coated nanolaminate comprising aluminum oxide (Al₂O₃), silicon oxide (SiO₂) and titanium oxide (TiO₂), wherein the encapsulant is antireflective, with at least one of a polyolefin, an ethyl vinyl acetate, and a silicone lamination over the nanolaminate.

8. The perovskite solar cell according to claim 1, wherein the hole transport layer is formed on an indium tin oxide (ITO), indium zinc oxide (IZO), or fluorine doped tin oxide (ITO) layer supported by a glass substrate.

9. The perovskite solar cell according to claim 1, wherein the hole transport layer is formed on an indium tin oxide (ITO), indium zinc oxide (IZO), or fluorine doped tin oxide (ITO) layer supported by a polyethylene terephthalate (PET) film.

10. A photoexcitable structure, comprising:
a perovskite layer adjacent to the hole transport layer, configured to generate photoexcited electrons and holes upon illumination;
a lithiated nickel oxide hole transport layer, configured to receive holes from the perovskite layer;
an electron transport layer configured to accept photoexcited electrons; and
a buffer later comprising a plurality of atomic layers of at least one resistive oxide having a thickness of less than 30 nm, between the perovskite layer and the electron transport layer, configured to impede hole transfer from the perovskite layer to the electron transport layer, and to impede ion migration and water diffusion.

11. The photoexcitable structure according to claim 10, further comprising a substrate having a conductive surface beneath the lithiated nickel oxide hole transport layer and a conductive layer over the electron transport layer, further comprising an encapsulant over the conductive layer.

12. The photoexcitable structure according to claim 10, wherein the at least one resistive oxide comprises a metal oxide selected from the group consisting of aluminum oxide, titanium oxide, tin oxide, silicon dioxide and zinc oxide.

13. A method of forming a perovskite solar cell, comprising:
forming a hole transport layer comprising nickel oxide with between 1-10% moles lithium per mole nickel;
forming a photoexcitable perovskite layer on the hole transport layer;
using atomic layer deposition to deposit layers of an oxide having a non-aqueous oxygen source on the perovskite layer; and
forming an electron transport layer over the deposited layers of the oxide.

14. The method according to claim 13, wherein the perovskite layer comprises at least one halogen, and the layers of the oxide are impermeable to the at least one halogen and water.

15. The method according to claim 13, wherein the layers of the oxide are more permeable to electrons than to holes.

16. The method according to claim 13, wherein the layers of the oxide comprise a metal oxide selected from the group consisting of aluminum oxide, titanium oxide, tin oxide, silicon dioxide and zinc oxide, deposited using a non-aqueous oxygen source.

17. The method according to claim 13, further comprising:
forming the hole transport layer on a conductive surface supported by a substrate;
depositing a conductive layer over the electron transport layer; and
forming an encapsulant over the conductive layer, the encapsulant comprising an atomic layer deposition (ALD) coated nanolaminate comprising aluminum oxide (Al₂O₃), silicon oxide (SiO₂) and titanium oxide (TiO₂) configured to be anti-reflective, followed by at least one of a polyolefin, an ethyl vinyl acetate, and a silicone lamination.

18. The method according to claim 13, wherein at least one layer is deposited in a pattern by an inkjet process.

19. The method according to claim 13, wherein the photoexcitable perovskite layer is formed using a two-step deposition process, comprising:
a first step in which a first mixture of lead(II) iodide (PbI₂), lead(II) bromide (PbBr₂), lead(II) chloride (PbCl₂), and cesium iodide (CsI) is prepared in a solvent mixture of dimethyl formamide (DMF) and dimethyl sulfoxide (DMSO) is deposited, dried and heated; and
a second step in which a second mixture of formamidinium iodide (FAI) and methylammonium bromide (MABr) are dissolved in anhydrous 2-propanol provided over the dried heated first mixture, and the second mixture is dried and annealed.

20. The perovskite solar cell according to claim 13, wherein the oxide layers comprises at least one of aluminum oxide (Al₂O₃), zinc oxide (ZnO), tin oxide (SnO), silicon dioxide (SiO₂₋ₓ) and titanium dioxide (TiO₂) buffer layers each less than 30 nm thick grown at temperatures below 150° C., formed using trimethyl-aluminum (TMA), dimethyl zinc (DMZ), tetrakis(dimethylamino) tin (TDMASn), Bis(diethylamino) silane (BDEAS) and titanium tetrachloride (TiCl₄) as metal precursor sources.

21. The perovskite solar cell according to claim 13, wherein the photoexcitable perovskite layer comprises a 2D perovskite.
